(19) United States
(12) Patent Application Publication
(10) Pub. No.: US 2020/0119205 A1
(43) Pub. Date: Apr. 16, 2020

(54) WAVEGUIDE-INTEGRATED PHOTODETECTOR

(71) Applicant: NEW YORK UNIVERSITY, New York, NY (US)

(72) Inventor: JACEK GOSCINIAK, LODZ (PL)

(21) Appl. No.: 16/653,042

(22) Filed: Oct. 15, 2019

Related U.S. Application Data
(60) Provisional application No. 62/745,518, filed on Oct. 15, 2018.

(51) Int. Cl. H01L 31/02; H01L 31/103

(52) U.S. Cl. CPC H01L 31/02005; H01L 31/1037

(57) ABSTRACT

An exemplary photodetector can be provided, which can include, for example, a metal contact, a metal stripe coupled to the metal contact, and a photon absorbing material(s) surrounding the metal stripe on at least four sides of the metal stripe. The photon absorbing material(s) can be germanium. The photon absorbing material(s) can be configured to absorb photons in a wavelength range of about 1.1 μm to about 1.7 μm.

### CROSS-REFERENCE TO RELATED APPLICATION(S)

This application relates to and claims priority from U.S. Patent Application No. 62/745,518, filed on Oct. 15, 2018, the entire disclosure of which is incorporated herein by reference.

### FIELD OF THE DISCLOSURE

The present disclosure relates generally to photodetectors, and more specifically, to exemplary embodiments of exemplary waveguide-integrated photodetector(s).

### BACKGROUND INFORMATION

The photodetectors (“PDs”) are one of the basic building blocks of an optoelectronic link that convert light into an electrical signal. The monolithic, on-chip, optoelectronic integration utilizes development of complementary metal-oxide-semiconductor (“CMOS”) compatible PDs operating in the telecom wavelengths (e.g., about 1.1-about 1.7 μm, which includes about 1.0-about 1.9 μm) based on the CMOS technology. (See, e.g., References 1-3). Although sensitivity is the most important attribute for photodetectors in long distance communications, for short distance interconnects the most critical factor is the total energy dissipated per bit. The optical energy received at photodetector is directly related to transmitter optical output power and the total link loss power budget, which includes total link attenuation, coupling losses and eventually, a power margin. Therefore, for 10 fJ/bit transmitted optical energies, the received optical energy can be 1 fJ/bit. (See, e.g., Reference 3). Thus, minimizing or otherwise reducing the optical losses at the photodetector can be beneficial for overall performance of the system. Photodetectors usually operate on the basis of the photoelectric effect or exhibit an electrical resistance dependent on the incident radiation. The operation principal is based on the absorption of photons and the subsequent separation of photogenerated charge carriers—electron-hole (e-h) pairs. They suffer however from low efficiency either because the NIR photons energy at telecom wavelengths (e.g., 0.79-0.95 eV) is not sufficient to overcome the Si bandgap (e.g., 1.12 eV), low detection area in the case of Ge-based photodetectors (e.g., bandgap 0.67 eV) or fabrication problems in the case of graphene-based photodetector. (See, e.g., Reference 1-3).

In terms of the operation schema, the photodetectors can be classified into four groups: (i) the photoconductive detectors, (ii) the p-i-n photodetectors, (iii) the tunnel junction photodetectors, and (iv) the Schottky detectors. (See, e.g., Reference 4) The photoconductive metal-semiconductor-metal (“MSM”) photodetectors are very attractive as they significantly reduce fabrication complexity and ensure high-speed operation. (See, e.g., References 5-7). In general, they include an absorber placed between two contacts under external bias. Under optical illumination, photons are absorbed by material and free charge carriers, electron-hole pairs, are generated increasing conductivity of the material. This creates the detectable photocurrent. When the light is removed, the process of charge photogeneration ceases, and the conductivity returns to its “dark” value as the excess electrons and holes recombine. Due to the absence of a depletion region, they usually have a high dark current. The MSM photodetector configuration can be more advantageous for high-speed application, owing to the small RC time product related to low capacitance and short transit time of carriers. (See, e.g., References 5 and 6).

Germanium (“Ge”) is often used in MSM configuration as it is compatible with CMOS process and it is a good active material for photodetection in the telecom wavelength range. Germanium belongs to the same group IV materials as Si so it can be easily integrated with a silicon platform. Compared to Si that has relatively large bandgap of 1.12 eV corresponding to an absorption cutoff wavelength of 1100 nm, the Ge direct bandgap of 0.8 eV is only 0.14 eV above the dominant indirect bandgap (e.g., 0.66 eV), which provides much higher optical absorption in the 1300-1550 nm wavelength range. This makes Ge-based photodetectors promising candidates for Si photonic integration. (See, e.g., References 5-7). Furthermore, compared to compound semiconductors that possess the advantage of higher absorption efficiency and higher carrier drift velocity but, simultaneously, suffer from integration problems with silicon platform, increased complexity and potential introduction of doping contaminants into the Si CMOS devices, Ge is easier to integrate with a silicon platform. (See, e.g., Reference 7). Thus, Ge is very popular material for integration with Si platform.

To achieve high responsivity, waveguide photodetector geometries are advantageous over surface illuminated photodetectors due to their ability to create longer absorption length without limiting their bandwidths. (See, e.g., References 4 and 5). In terms of a waveguide coupling from the Si waveguide to the Ge photodetector, two coupling schemas can be considered: (i) evanescent coupling and (ii) butt coupling. (See, e.g., Reference 7). The butt-coupled photodetectors are more efficient, which results in shorter Ge absorption length and lower capacitance. However, the evanescently coupled photodetectors are generally easier to fabricate and most practical when the absorption region is grown, rather than bonded. (See, e.g., Reference 7).

Plasmonics photodetectors are attracting the attention of the photonics community as they have the ability to confine light below diffraction limit that facilitates the light-matter interaction on a deep subwavelength scale. It facilitates shrinking of the device size, which brings the technology one step closer to a fusion of optical and electronic components at the same size scale. In addition, plasmonics can boost the operation speed. As with all other plasmonic devices, interconnects, the plasmonic photodetectors naturally include metallic elements that can constitute the absorber in hot-carrier devices, or provide enhancement of electromagnetic field inside an absorber. (See, e.g., References 4 and 8).

Thus, it may be beneficial to provide an exemplary waveguide-integrated photodetector which can overcome at least some of the deficiencies described herein above.

### SUMMARY OF EXEMPLARY EMBODIMENTS

An exemplary photodetector can be provided, which can include, for example, a metal contact, a metal stripe coupled to the metal contact, and a photon absorbing material(s) surrounding the metal stripe on at least four sides of the metal stripe. The photon absorbing material(s) can be germanium or any other photoconductive material able to generate the electron-hole pairs. The photon absorbing material(s) can be configured to absorb photons in a broad wavelength range. A further metal contact can be disposed on the photon absorbing material(s). A voltage generator(s) can be included, which can be configured to apply a bias voltage between the metal contact and the further metal contact to generate an electric field in the photon absorbing material(s). The metal contact can be disposed on the photon absorbing material(s).

In some exemplary embodiments of the present disclosure, a semiconductor layer can be included, which can be disposed on the semiconductor layer. The semiconductor layer can be silicon dioxide. A further photon absorbing material can be disposed on the semiconductor layer adjacent to the photon absorbing material(s). The further photon absorbing material(s) can be silicon. The further photon absorbing material(s) can include a slab and a ridge extending from the slab. A low refractive index substrate can be included, which can be disposed on the low refractive index substrate. The photon absorbing material(s) can include a slab and a ridge extending from the slab, and the metal contact can be disposed on the slab and the metal strip can be (i) disposed between the ridge and the slab, (ii) disposed entirely in the ridge, or (iii) inside the slab. The metal contact and the metal strip can be composed of one of Titanium nitride, aluminum, copper, silver, gold, or zirconium nitride.

Additionally, an exemplary photodetector can be provided, which can include, for example, a metal contact, a metal stripe coupled to the metal contact, and a layer of graphene(s) located between the metal stripe and a semiconductor layer. The layer of graphene(s) can be coupled to the metal contact. The exemplary photodetector can include a further metal contact(s) can, and the layer of graphene(s) can be coupled to the further metal contact(s). A photon absorbing material(s) can be included, which can surround the metal stripe on at least four sides of the metal stripe, and the photon absorbing material(s) can be germanium.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1 is an exemplary cross-sectional diagram of a Ge plasmonic photodetector according to an exemplary embodiment of the present disclosure;

FIGS. 2A-2C are exemplary diagrams of cross-sections of the exemplary waveguide/photodetector according to an exemplary embodiment of the present disclosure;

FIGS. 3A and 3C are exemplary plots illustrating mode effective index and mode power attenuation images according to an exemplary embodiment of the present disclosure;

FIGS. 3B and 3D are exemplary plots illustrating a propagation distance according to an exemplary embodiment of the present disclosure;

FIGS. 4A and 4B are further exemplary plots illustrating mode effective index and mode power attenuation images according to an exemplary embodiment of the present disclosure;

FIGS. 4B and 4D are further exemplary plots illustrating propagation distance according to an exemplary embodiment of the present disclosure;

FIGS. 5A and 5C are exemplary contour plots according to an exemplary embodiment of the present disclosure;

FIGS. 5B and 5D are exemplary graphs illustrating electric field profiles according to an exemplary embodiment of the present disclosure;

FIG. 6 is an exemplary graph illustrating a comparison of the losses in metallic stripe/contact on quantum efficiency according to an exemplary embodiment of the present disclosure;

FIGS. 7A-7C are exemplary diagrams of bands of a Au—Ge—Au structure according to an exemplary embodiment of the present disclosure;

FIG. 8A is an exemplary graph illustrating real parts of permittivities of some metals used in plasmonics according to an exemplary embodiment of the present disclosure;

FIG. 8B is an exemplary graph illustrating imaginary parts of permittivities of some metals used in plasmonics according to an exemplary embodiment of the present disclosure;

FIG. 9 is an exemplary graph illustrating a complex graphene refractive index according to an exemplary embodiment of the present disclosure;

FIGS. 10A and 10B are exemplary schematic diagrams of graphene-based photodetectors according to an exemplary embodiment of the present disclosure;

FIGS. 11A-11D are exemplary diagrams of the cross-section of a graphene-based photodetector according to an exemplary embodiment of the present disclosure;

FIG. 12A is an exemplary plot of the transverse magnetic mode with calculated mode effective index and mode power attenuation without the use of graphene according to an exemplary embodiment of the present disclosure;

FIG. 12B is an exemplary plot of the transverse magnetic mode with calculated mode effective index and mode power attenuation with the use of graphene according to an exemplary embodiment of the present disclosure;

FIG. 13A is an exemplary plot of the transverse electric mode with calculated mode effective index according to an exemplary embodiment of the present disclosure;

FIG. 13B is an exemplary plot of the transverse magnetic mode with calculated mode effective index according to an exemplary embodiment of the present disclosure;

FIGS. 14A and 14B are exemplary plots illustrating the mode with calculated mode effective index and mode power attenuation for transverse electric mode according to an exemplary embodiment of the present disclosure;

FIGS. 14C and 14D are exemplary plots illustrating the mode with calculated mode effective index and mode power attenuation for transverse magnetic mode according to an exemplary embodiment of the present disclosure;

FIGS. 15A and 15B are further exemplary plots illustrating the mode with calculated mode effective index and mode power attenuation for transverse electric mode according to an exemplary embodiment of the present disclosure;

FIGS. 15C and 15D are further exemplary plots illustrating the mode with calculated mode effective index and mode power attenuation for transverse magnetic mode according to an exemplary embodiment of the present disclosure;

FIGS. 16A and 16B are exemplary contour plots of the transverse magnetic mode of the exemplary waveguide according to an exemplary embodiment of the present disclosure;

FIG. 16C is an exemplary graph illustrating the out-of-plane component of the electric field of the mode taken in the middle of the exemplary waveguide according to an exemplary embodiment of the present disclosure;

FIG. 16D is an exemplary graph illustrating the in-plane component of the electric field of the mode taken along graphene that is a part of the exemplary waveguide according to an exemplary embodiment of the present disclosure;

FIGS. 17A and 17B are exemplary contour plots of the transverse electric mode of the exemplary waveguide according to an exemplary embodiment of the present disclosure;

FIG. 17C is an exemplary graph illustrating the in-plane component of the electric field of the mode taken in the center of metal stripe of the exemplary waveguide according to an exemplary embodiment of the present disclosure;

FIG. 17D is an exemplary graph illustrating the in-plane component of the electric field of the mode taken on top of the graphene sheet/layer of the exemplary waveguide according to an exemplary embodiment of the present disclosure;

FIG. 18 is a set of exemplary band diagrams of graphene photodetectors with different sources/drains metal configurations according to an exemplary embodiment of the present disclosure;

FIG. 19A is an exemplary graph of the wavelength dependent real parts of permittivities of different plasmonic materials used by the exemplary waveguide according to an exemplary embodiment of the present disclosure;

FIG. 19B is an exemplary graph of the wavelength dependent imaginary parts of permittivities of different plasmonic materials used by the exemplary waveguide according to an exemplary embodiment of the present disclosure;

FIG. 20 is an exemplary graph illustrating absorption coefficients of Si and Ge on Si and SiO₂ according to an exemplary embodiment of the present disclosure;

FIG. 21A is an exemplary diagram of the exemplary Ge LR-DLSPP photodetector arrangement according to an exemplary embodiment of the present disclosure;

FIG. 21B is an exemplary diagram illustrating the cross-section of the exemplary Ge LR-DLSPP photodetector arrangement according to an exemplary embodiment of the present disclosure;

FIG. 21C is an exemplary plot of the mode effective index for a Si photonics rib waveguide according to an exemplary embodiment of the present disclosure;

FIG. 21D is an exemplary plot of the mode effective index of the exemplary Ge LR-DLSPP waveguide arrangement according to an exemplary embodiment of the present disclosure;

FIG. 22A is an exemplary plot of the generation rate at the middle of the photodetector for the exemplary LR-DLSPP arrangement according to an exemplary embodiment of the present disclosure;

FIG. 22B is an exemplary plot of the generation rate at the middle of the photodetector for the exemplary MIM photodetector arrangement according to an exemplary embodiment of the present disclosure;

FIG. 22C is an exemplary graph illustrating a comparison of the losses in metallic stripe/contact on quantum efficiency as a function of the device length for LR-DLSPP and asymmetric MIM arrangements according to an exemplary embodiment of the present disclosure;

FIG. 23A is an exemplary graph illustrating the total power absorbed by a germanium photodetector at wavelengths of 1310 nm and 1550 nm according to an exemplary embodiment of the present disclosure;

FIG. 23B is an exemplary graph illustrating germanium photodetector responsivity as a function of the reserve bias for different device lengths and wavelengths according to an exemplary embodiment of the present disclosure;

FIG. 24A is an exemplary band diagram of the exemplary Au—Ge—Au structure without bias for a centered illuminated light according to an exemplary embodiment of the present disclosure;

FIGS. 24B and 24C are exemplary band diagrams of the exemplary Au—Ge—Au structure with bias according for a centered illuminated light (FIG. 24B) and edge illuminated light (FIG. 24C) to an exemplary embodiment of the present disclosure;

FIGS. 25A-25D are exemplary plots of the mode with calculated mode effective index and corresponding MPAs for different distance for an external electrode according to an exemplary embodiment of the present disclosure;

FIG. 25E is an exemplary graph illustrating normalized frequency response for different bias voltages according to an exemplary embodiment of the present disclosure;

FIG. 26 is an exemplary schematic diagram illustrating the photo-thermoelectric effect principles according to an exemplary embodiment of the present disclosure;

FIG. 27A is an exemplary schema of the exemplary graphene photodetector according to an exemplary embodiment of the present disclosure;

FIG. 27B is an exemplary cross-sectional diagram of the exemplary graphene photodetector and an associated Poynting vector field distribution according to an exemplary embodiment of the present disclosure;

FIGS. 28A and 28B are exemplary plots of the calculated E² of the exemplary LR-DLSPP waveguide mode according to an exemplary embodiment of the present disclosure;

FIG. 28C is an exemplary graph and corresponding plot of the calculated absorption efficiency versus photoelector length for the exemplary photodetector according to an exemplary embodiment of the present disclosure;

FIG. 28D is an exemplary graph illustrating the propagation losses versus distance between electrodes for a structure without graphene and with graphene according to an exemplary embodiment of the present disclosure;

FIG. 29A is an exemplary graph illustrating the conductivity of graphene for different charge neutrality widths according to an exemplary embodiment of the present disclosure;

FIG. 29B is an exemplary graph illustrating the electron thermal conductivity of graphene for different charge neutrality widths according to an exemplary embodiment of the present disclosure;

FIG. 29C is an exemplary graph illustrating the cooling rate of carriers in graphene for different charge neutrality widths according to an exemplary embodiment of the present disclosure;

FIG. 29D is an exemplary graph illustrating the cooling length of carriers in graphene for different charge neutrality widths according to an exemplary embodiment of the present disclosure;

FIG. 30A is a further exemplary graph illustrating the cooling rate of carriers in graphene for different charge neutrality widths according to an exemplary embodiment of the present disclosure;

FIG. 30B is a further exemplary graph illustrating the cooling length of carriers in graphene for different charge neutrality widths according to an exemplary embodiment of the present disclosure;

FIG. 30C is an exemplary temperature map of carriers in graphene according to an exemplary embodiment of the present disclosure;

FIG. 30D is a further exemplary temperature map of carriers in graphene according to an exemplary embodiment of the present disclosure;

FIG. 30E is an exemplary graph illustrating a comparison of temperature distributions between metal contacts and along a graphene layer/sheet according to an exemplary embodiment of the present disclosure;

FIG. 31A is an exemplary diagram illustrating a pointing vector field distribution between a metal stripe contact and an external electrode and along a graphene layer/sheet according to an exemplary embodiment of the present disclosure;

FIG. 31B is an exemplary graph illustrating the temperature rise in graphene as a function of the chemical potential according to an exemplary embodiment of the present disclosure;

FIGS. 31C and 31D are exemplary temperature maps for graphene according to an exemplary embodiment of the present disclosure;

FIGS. 32A, 32B, 32D, 32E, 32G and 32H are exemplary photocurrent maps of the exemplary arrangement according to an exemplary embodiment of the present disclosure;

FIGS. 32C, 32F and 32I are exemplary graphs illustrating photocurrent (arbitrary units) versus chemical potential according to an exemplary embodiment of the present disclosure;

FIG. 33A is an exemplary graph illustrating the resistance of a graphene sheet for different charge neutrality widths according to an exemplary embodiment of the present disclosure;

FIG. 33B is an exemplary graph illustrating photodetector responsivity for different charge neutrality widths according to an exemplary embodiment of the present disclosure;

FIG. 33C is an exemplary photocurrent map of the exemplary photodetector according to an exemplary embodiment of the present disclosure;

FIG. 33D is an exemplary graph illustrating the photocurrent as a function of the chemical potential according to an exemplary embodiment of the present disclosure;

FIGS. 34A-34C are exemplary band diagrams of the exemplary graphene photodetector with different source/metal combinations according to an exemplary embodiment of the present disclosure; and

FIG. 35 is an illustration of an exemplary block diagram of an exemplary system in accordance with certain exemplary embodiments of the present disclosure

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF EXEMPLARY EMBODIMENTS

### Exemplary Waveguide-Integrated Photoconductive Plasmonic Photodetector

The exemplary plasmonic photodetector can be based on a surface plasmon polariton (“SPP”) waveguide arrangement with the germanium absorbing material as one of the examples of photoconductive materials. However, it should be noted that other suitable photoconductive materials can also be used.

SPPs are electromagnetic (“EM”) waves that can be coupled to surface collective oscillations of free electrons in a metal bounded to the metal and propagating along metal-dielectric/semiconductor interfaces. (See, e.g., References 9-11). They can range from localized surface plasmons (“LSPs”) of individuals particles to various propagating SPPs existing at flat, curved, single or multiple surfaces. (See, e.g., Reference 9). LSP modes bring about unique plasmonic phenomena of subwavelength light confinement and EM field enhancement resulting in extreme light concentration. SPP modes can also be strongly localized in the cross-section perpendicular to the propagation direction. However, they suffer from inevitable EM absorption in metals. SPP-based waveguides can transport the same huge bandwidth of information as conventional photonics waveguides, while not limited by diffraction limit. (See, e.g., Reference 9).

As indicated above, one of the challenges shared by plasmonic structures can be considerable plasmonic losses due to absorption by the metal that increases drastically for better confinement modes. The presence of a metal within the structure introduces losses simultaneously, which facilitates the co-propagation of overlapping electric and photonic signals and thus can be of great interest. It can provide ways to generate, modulate and detect light shrinking dimensions towards the scale of electronic. (See, e.g., References 4 and 9). The presence of a metal electrode at the electric field maximum of the propagating SPP mode greatly enhances the sensitivity to an applied electrical signal. An obstacle for realization of plasmonic devices can be a limited propagation length of the optical signal within a plasmonic waveguide, which can be a direct result of light absorption in the metal. In the last decade, various plasmonic waveguide configurations were proposed and demonstrated to tackle this problem. These include gap (e.g., metal-insulator-metal) (see, e.g., References 8 and 9), metal stripe (see, e.g., Reference 9), V-groove (see, e.g., Reference 9), nanowires (see, e.g., Reference 9), dielectric-loaded SPP (“DLSPP”) (see, e.g., References 9 and 14), and long-range SPP (“LR-SPP”). (See, e.g., Reference 9). However, they have either poor more confinement or short propagation length; for example, long propagation length of the signal can be achieved at the expense of weak spatial confinement.

### Exemplary Long-Range Dielectric Loaded Surface Plasmon Polariton (“LR-DLSPP”)

LR-DLSPP inherits many advantages of having a very long propagation length from long-range SPP (“LR-SPP”) waveguide, and good mode confinement from the DLSPP waveguide. (See, e.g., References 9-13). LR-DLSPP includes a semiconductor/dielectric ridge deposited on top of a thin metal stripe/electrode, which can be supported by other semiconductor slab from a bottom. The entire structure can be supported by a low-index substrate which can ensure mode confinement to the semiconductor/dielectric ridge and underlying semiconductor/dielectric slab. Due to the thin metal film, the SPPs on the two metal-semiconductor/dielectric interfaces can couple to each other and form a supermode with symmetric and anti-symmetric transverse components. The symmetric mode, long-range mode, can be characterized by low longitudinal component of the electric field in the metal, thus lowering the absorption losses. Long propagation distance can be achieved when mode effective indexes on both metal-semiconductor/dielectric interfaces can be close to each other such that they can couple together minimizing an electric field in the metal. Thus, LR-DLSPP can provide very high propagation length and reasonable mode confinement. In comparison, a gap SPP (“MIM”) can support very high confined SPP mode, but absorption losses arising from a metal can limit the propagation distance to tens of the corresponding mode wavelengths. LR-DLSPP can facilitate superior mode field confinement and high propagation length. (See, e.g., References 9-13). It can have the highest evaluated a figure of merit (“FoM”) among any other plasmonic waveguides that takes into account mode size, wavelength, and propagation length (see, e.g., Table 1 below) (see, e.g., References 9 and 11). Thus, for example:

$$FoM = {L}_{p}^{2} \frac{{λ}_{0}}{{n}_{{effw}_{0}^{3}}} \qquad ( 1 )$$

where w₀ can be the lateral mode width, Lₚ can be the mode propagation length, n_{eff} can be the mode effective index, and λ₀ can be the excitation wavelength.

The FoM for LR-DSLPP was much higher, at least of two orders magnitude, compared to any other plasmonic waveguide configurations (see, e.g., Table 1 below). (See, e.g., References 9 and 11).

TABLE 1
FoM for plasmonic waveguides.

| Wave- | | | | Gap | |
|---|---|---|---|---|---|
| guide | LR-DLSPP | LR-SPP | DLSPP | (MIM) | V-grove |
| FoM | 3.2 · 10⁶ | 3.2 · 10⁴ | 3.4 · 10³ | 1.1 · 10⁴ | 2.9 · 10⁴ |

Furthermore, the LR-DLSPP mode profile matches very well the mode of the photonic waveguide, thus facilitating efficient coupling between photonics and plasmonic platforms. LR-DLSPP waveguide mode supporting a TM mode can have a similar mode profile to the photonic TM mode with the overlap integral between them showing up to 98% coupling efficiency with superior tolerance to the offset of the metal stripe supporting the LR-DLSPP mode. (See, e.g., References 12 and 13)

### Exemplary Ge Photodetector

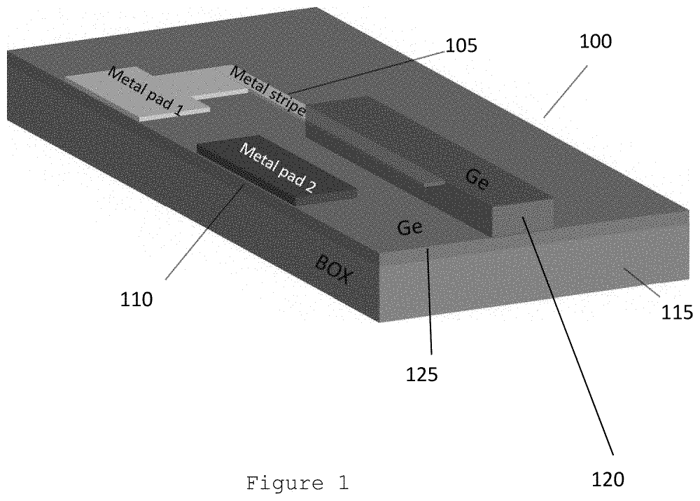

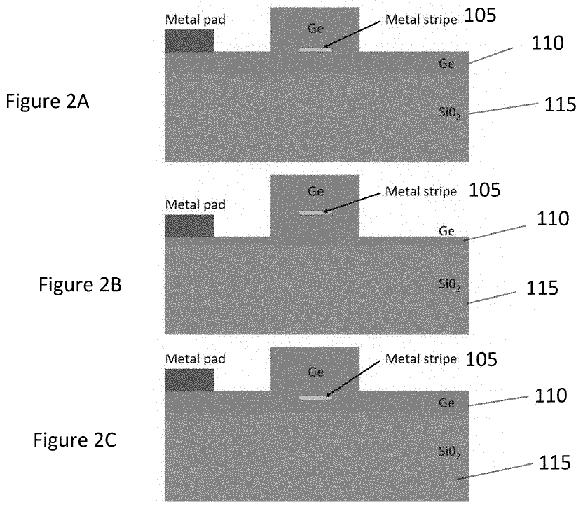

FIG. 1 shows an exemplary cross-sectional diagram of a Ge plasmonic photodetector according to an exemplary embodiment of the present disclosure. The exemplary photoconductive Ge photodetector 100 can be based on the absorption of LR-DLSPP plasmonic mode by Ge propagating in the germanium waveguide. (See, e.g., diagrams shown in FIGS. 1 and 2A-2C). As the optical energy is confined in the waveguide the efficient photodetection process can take place. By applying a bias voltage between the two metallic contacts (e.g., metal pad 1 and metal pad 2 shown in FIG. 1), an electric field can be generated in the Ge (e.g., in Ge layer 110, which can be formed on semiconductor layer 115). Consequently, the generated electron-hole (e-h) pairs in germanium can be efficiently separated and strongly accelerated by the applied field. These separated carriers can drift toward metallic contacts (e.g., metal pad 1 and metal pad 2), generating a photoinduced current proportional to the intensity of the optical signal. In the exemplary arrangement, the metal stripe 105 supporting a propagating mode can be placed either between a ridge 120 and a slab 125 (see, e.g., diagram shown in FIG. 2A), entirely inside ridge 120 (see, e.g., diagram shown in FIG. 2B) or slightly inside slab 125 (see, e.g., diagram shown in FIG. 2C) while still providing superior mode guiding properties and minimum absorption losses in the stripe.

### Exemplary Quantum Efficiency

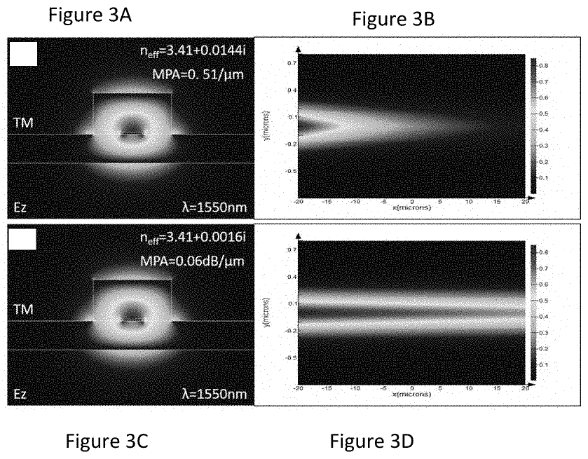

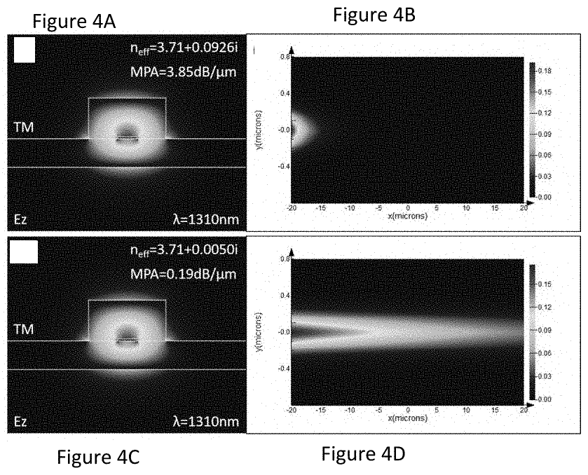

Neglecting the scattering losses, the responsivity of the photodetector can depend only on the absorption coefficient of Ge, α_{Ge}, and metal, αₘ. The material absorption of Ge and the confinement factor of the mode in the Ge waveguide can be used to determine α_{Ge}. Also, the overlap of the mode with the metal can be used to determine αₘ. (See, e.g., Reference 7). To calculate the absorption coefficients of metal (e.g., Au), α_{Au}, and Ge, α_{Ge}, the 3D FDTD and FEM simulations were performed. To determine α_{Au}, the Ge absorption coefficient was set to 0 and Au stripe/electrode (see, e.g., diagrams shown in FIGS. 2A-2C) was described by a complex refractive index. The reduction in the amplitude of the transmission through the LR-DLSPP waveguide was assigned to absorption by the Au stripe/electrode. Thus, an effective absorption of Au stripe/electrode, α_{Au}, was calculated at α_{Au}=130 cm⁻¹ and α_{Au}=182 cm⁻¹ for wavelengths of λ=1550 nm (see, e.g., contour plots shown in FIGS. 3A-3D) and λ=1310 nm (see, e.g., contour plots shown in FIGS. 4A-4D), respectively. In order to obtain α_{Ge}, the absorption coefficient of Au was set to 0, and Ge was described by a complex refractive index, thus, the losses were assigned to the absorption of the Ge waveguide. The effective absorptions of Ge were calculated at α_{Ge}=920 cm⁻¹ and α_{Ge}=7956 cm⁻¹ for wavelengths of λ=1550 nm (see, e.g., contour plots shown in FIGS. 3A-3D) and λ=1310 nm (see, e.g., plots shown in FIGS. 4A-4D), respectively.

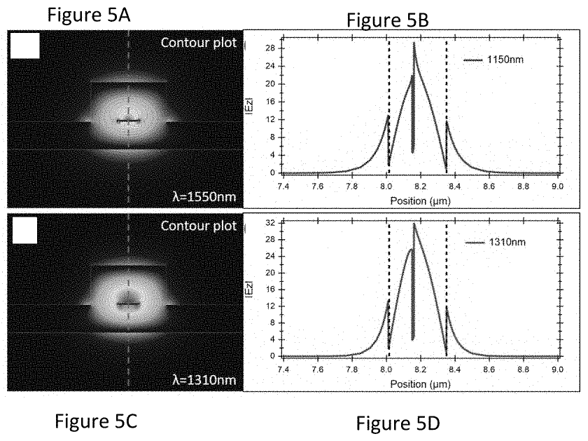

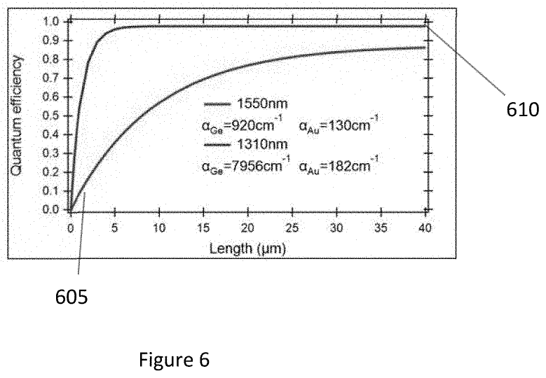

FIGS. 5A and 5C show exemplary plots according to an exemplary embodiment of the present disclosure. FIGS. 5B and 5D show exemplary graphs illustrating electric field profiles according to an exemplary embodiment of the present disclosure. FIG. 6 shows an exemplary graph illustrating a comparison of the losses in metallic stripe/contact on quantum efficiency according to an exemplary embodiment of the present disclosure. As shown in FIG. 6, the quantum efficiencies exceeding 97.7% and 86.3% can be achieved for wavelength of λ=1310 nm (e.g., line 605) and λ=1550 nm (e.g., line 610), respectively. Only L=24 μm long photodetector may be used to achieve the quantum efficiency over 80% from wavelength of λ=1550 nm, while for wavelength of λ=1310 nm, the quantum efficiency of 96% was possible for only L=5 μm long photodetector. There are record high results, illustrating the realization of very efficient and fast Ge photodetector. (See, e.g., References 7 and 8). In comparison, to other plasmonic waveguide arrangements (see, e.g., Reference 7), 75% quantum efficiency was achieved at λ=1310 nm for L=10 μm long Germanium-on-insulator (“GOI”) photonic photodetector while for λ=1550 nm, it was only 20% and it utilized a photodetector length of L=20 μm. The results were compared with other plasmonic Ge photodetector realized in metal-insulator-metal (“MIM”) plasmonic waveguide arrangement, with Ge placed in a slot of width d=120-160 nm between Au electrodes, where 75% a quantum efficiency was calculated for L=10 μm long photodetector at wavelength of λ=1310 nm, and only 30% a quantum efficiency for L=50 μm long photodetector at λ=1550 nm. (See, e.g., Reference 8). Compared to those results, the exemplary plasmonic photodetector shows huge improvement in terms of quantum efficiency and photodetector length. The smaller photodetector footprint means lower RC and higher operation speed of the photodetector. This can be based on superior mode field confinement in the entire active area (see, e.g., contour plots shown in FIGS. 5A and 5C, and graphs shown in FIGS. 5B and 5D) and reduce losses related with the metal stripe/electrode. (See, e.g., field plots shown in FIGS. 3A-4D).

In the exemplary arrangement, the absorption coefficient of Ge, α_{Ge}, can be at least 7 times higher compared to the absorption coefficient of Au, α_{Au}, for a wavelength of λ=1550 nm, and over 43 times higher for a wavelength of λ=1310 nm where Ge shows a higher absorption. (See, e.g., graph shown in FIG. 6). For both previously-described arrangements (see, e.g., References 7 and 8), the α_{Ge} was always lower compared to α_{Au}. Thus, for GOI photonic waveguide (see, e.g., Reference 7), α_{Ge} was 10 times lower compared to α_{Au} for wavelength of λ=1550 nm and almost the same for wavelength of λ=1310 nm. Similar trend can be observed for the MIM Ge photodetector. (See, e.g., Reference 8).

### Exemplary Speed (Bandwidth)

In telecommunication systems, photodetectors can be used to detect optical signals modulated at high data rates. Thus, an important metric can be the opto-electrical 3 dB bandwidth, which can be defined as the frequency range from DC to cut-off frequency f_{3dB}, for example, the frequency at which the electrical output power drops by 3 dB below power value at very low frequency. The opto-electronic bandwidth of a photodetector can depend on the carrier transit time and RC response time. To reduce the carrier transit time, the distance between the collecting electrodes can be small. In comparison, RC time reduction can be obtained by lowering the contact resistance of the metal electrodes and by reducing the detector length what reduce the photodetector capacitance. (See, e.g., Reference 15). The RC-limited 3 dB cut-off frequency can be expressed as, for example:

$${f}_{RC} = \frac{1}{2 π {R}_{eff} {C}_{pd}} \qquad ( 2 )$$

where R_{eff} can be the effective overall resistance and C_{pd} can be the junction capacitance. The carrier transit time, that defines the time of photogenerated electron or hole to travel through the active region prior to being collected by the contacts, can be estimated using, for example:

$${f}_{t} \approx \frac{3.5 v}{2 π {d}_{abs}} \qquad ( 3 )$$

where d_{abs} can be a distance between areas where carriers generate and the electrode collecting those carriers, and v can be the average carrier velocity.

As discussed above, only L=5 μm long photodetector may be used to achieve a quantum efficiency exceeding 95% at wavelength of 1310 nm. Taking into account a distance between both electrodes in the range of 450 nm, for example, the second electrode can be placed around 300 nm from the Ge waveguide, the capacitance in a range of a few fF can be suspected. The second electrode placed 300 nm from the waveguide may not disturb a propagating mode in the waveguide, what can translate into small propagation losses and can be associated with small absorption by a metal electrode supporting a propagating mode, which gives a rise to enhanced quantum efficiency and responsivity. If the device/photodetector can be connected with a 50Ω load, the RC cut-off frequency exceeding a 1 THz can be achieved.

In the exemplary design/configuration, all carriers can be generated in the area limited by the semiconductor ridge. Thus, the maximum distance between photogenerated carriers and the electrode, collecting those carriers, being at the same time the metal stripe supporting a propagating mode, can be around d_{abs}=200 nm. Taking a drift velocity of 600 μm/s, the bandwidth of fₜ=160 GHz can be achieved. However, as it can be observed from the field plots and graph 5 shown in FIGS. 5A-5D, over 90% of absorbed power can be located around 100 nm from the collecting metal electrode. Thus, a bandwidth of 320 GHz can be achieved which illustrates a high prospect in realization of high bandwidth photodetectors based on LR-DLSPP waveguide arrangement. Because of the nature of SPP that facilitates strong light concentration in the near-field, most of the carriers can be generated in very close proximity to the metal stripe/electrode. As a result, the average photogenerated electron path length to the metal electrode can be significantly reduced in comparison with conventional photoconductive photonic photodetectors. (See, e.g., Reference 16). Thus, the exemplary photogenerated carriers can reach a metal electrode much faster even in the case of the absorbing materials with relatively low drift velocity in the semiconductor. Furthermore, a large portion of the photogenerated electrons can reach the contact in a subpicosecond timescale, which improves the operation bandwidth and the photodetector efficiency, and responsivity. In conventional photoconductive photodetectors, the majority of the photogenerated carriers can recombine in the substrate before reaching the contact electrodes. (See, e.g., Reference 16). As the result, the exemplary photodetector can provide a bandwidth exceeding 300 GHz.

As discussed herein, the bandwidth of the photodetector is not limited by a RC time constant; however, the transit time used for carriers to drift to contact electrode collecting the carriers can be beneficial. By decreasing the distance between the two contacts, a large electric field can be obtained at low bias voltage, which improves the carriers' collection.

### Exemplary Symmetric and Asymmetric Electrodes

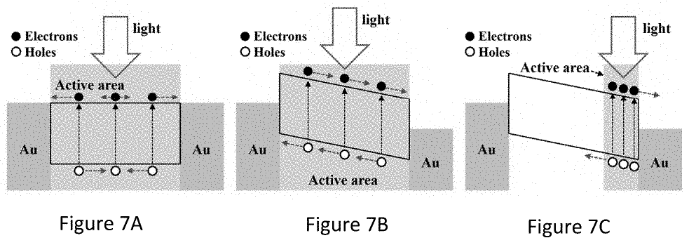

FIGS. 7A-7C show exemplary diagrams of bands of the Au—Ge—Au structure according to an exemplary embodiment of the present disclosure. Compared to a previous waveguide arrangements where carriers were generated in the entire area limited only by metal contacts (see, e.g., diagrams shown in FIGS. 7A and 7B) (see, e.g., References 7 and 8) (e.g., without a bias voltage (see, e.g., schematic diagram shown in FIG. 7A) and under a bias voltage (see, e.g., diagram shown in FIG. 7B)), in the exemplary arrangement the carriers can be generated only close to the metal electrode/contact supporting a propagating mode (see, e.g., diagram shown in FIG. 7C, under a bias voltage). Thus, a transit time for carriers to reach the electrode can be extremely fast. The metal electrodes/contacts can include the same metals creating the symmetric structure, or they can create an asymmetric structure by using two different metals. In terms of the metal electrodes supporting a propagating mode, the electrode can provide superior plasmonic properties defined by the real and imaginary parts of the permittivity. Thus, the real part of the permittivity can be negative with the value as high as possible. Simultaneously, to minimize the propagation losses related with the absorption, the imaginary part of the permittivity can be as small as possible in the desired wavelengths range.

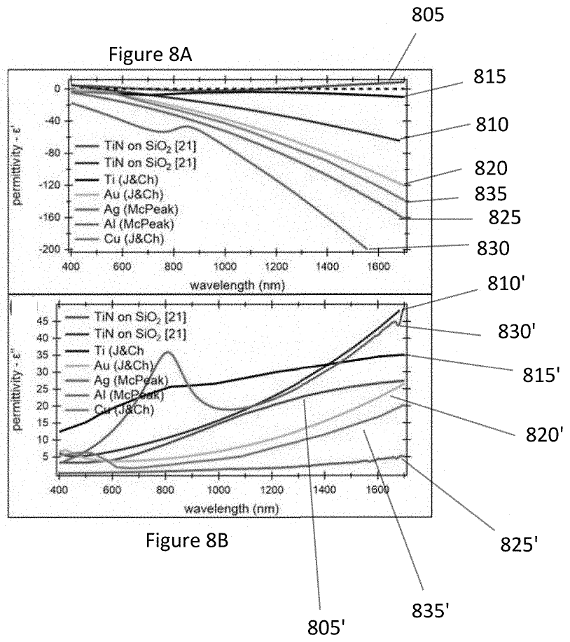

Previously, a new class of plasmonic materials appeared, so called transition metal nitrides (“TMNs”) that offer the optical properties close to that of noble metals. (See, e.g., graphs shown in FIGS. 8A and 8B). (See, e.g., References 17 and 18). In particular, FIG. 8A shows an exemplary graph illustrating real parts of the permittivities of metals (e.g., TiN on Si0₂ 805, TiN on SiO₂ 810 fabricated under different working conditions, Ti 815, Au 820, Ag 825, Al 830, and Cu 835) used in plasmonics according to an exemplary embodiment of the present disclosure, and FIG. 8B shows an exemplary graph illustrating imaginary parts of the permittivities of metals (e.g., TiN on Si0₂ 805′, TiN on SiO2 810′ fabricated under different working conditions, Ti 815′, Au 820′, Ag 825′, Al 830′, and Cu 835′) used in plasmonics according to an exemplary embodiment of the present disclosure. TiN offers high temperature durability, CMOS compatibility while their optical properties strongly depend on the deposition conditions. (See, e.g., References 17 and 18). TMNs, such as for example TiN, are CMOS compatible, it can be integrated in the exemplary LR-DLSPP photodetector waveguide arrangement providing more flexibility in the design process. Thus, it can facilitate the designing of the photodetector with the asymmetric metallic contacts, where TiN can be arranged either as an external electrode (e.g., metal pad 1 shown in FIG. 1) or a metal electrode supporting a propagating plasmonic mode (see e.g., FIG. 1). Furthermore, other materials illustrating superior plasmonic properties such as aluminum, copper, silver, gold, zirconium nitride (ZrN) and others, can be used as a metal stripes supporting a propagating mode. (See, e.g., graphs shown in FIGS. 8A and 8B). In cases of an external electrode, all materials showing superior electrical properties can be implemented in the exemplary arrangement. It was previously shown, that asymmetric metallic contacts can minimize a dark current in the photodetector. (See, e.g., References 19 and 20). This can also be performed by adding a thin barrier with a large bandgap material between metal contacts and germanium. (See, e.g., Reference 21).

### Exemplary Waveguide-Integrated Plasmonic Graphene Photodetector

The PDs are one of the basic building blocks of an optoelectronic link that convert light into an electrical signal. The monolithic, on-chip, optoelectronic integration utilizes development of CMOS compatible PDs operating in the telecom wavelengths (1.1-1.7 μm) based on the CMOS technology. (See, e.g., References 22-24). Although sensitivity can be an important attribute for photodetectors in long distance communications, for short distance interconnects an important factor can be the total energy dissipated per bit. The optical energy received at a photodetector can be directly related to the transmitter optical output power and the total link loss power budget, which can include total link attenuation, coupling losses and eventually, a power margin. Therefore, for 10 fJ/bit transmitted optical energies, the received optical energy can be 1 fJ/bit. Thus, minimizing the optical losses at the photodetector can be beneficial for overall performance of the system. Photodetectors usually operate on the basis of the photoelectric effect or exhibit an electrical resistance dependent on the incident radiation. The operation principal can be based on the absorption of photons and the subsequent separation of photogenerated charge carriers—electron-hole (e-h) pairs. They suffer, however, from low efficiency either because the NIR photons energy at telecom wavelengths (e.g., 0.79-0.95 eV) may not be sufficient to overcome the Si bandgap (e.g., 1.12 eV) or low detection area in the case of Ge-based photodetectors (e.g., bandgap 0.67 eV). The alternative approach utilizes the intrinsic absorption of graphene integrated with a photonic platform for photodetection.

Graphene can be very attractive material for photonic and optoelectronics because it offers a wide range of advantages compared to other materials. Single-layer graphene absorbs 2.3% of the incident light, which can be remarkably high for an atomically thin material. Graphene can be gapless what can facilitate charge carrier generation by light absorption over a very wide energy spectrum. It can have ultrafast carrier dynamics, wavelength-independent absorption, tunable optical properties, high mobility, and the ability to confine electromagnetic energy to very small volumes. (See, e.g., Reference 4). The high carrier mobility (e.g., both electrons and holes) can facilitate ultrafast conversion of photons or plasmons to electrical currents or voltages. By integration with local gates, this process can be in situ tunable and can facilitate submicron detection resolution. (See, e.g., References 5-7). Furthermore, graphene can be integrated onto silicon-based systems on wafer-scale. By integration of graphene with the propagating photonic mode, the interaction length of the mode with graphene can be greatly enhanced compared to the normal incidence situation in which the interaction length can be limited by the thickness of graphene. These graphene photodetectors have the additional advantage of process compatibility with standard photonic integrated circuits. (See, e.g., References 29-22). The absorption of graphene is described in terms of the optical conductivity which can be calculated from the Kubo formula that can depend on the angular frequency ω, the charge particle scattering rate F, the chemical potential μ, and temperature T. Thus, the relative conductivity ε_{eff} of graphene can be calculated from, for example:

$${ɛ}_{eff} = 1 + \frac{i σ}{ω {ɛ}_{0} Δ} \qquad ( 4 )$$

where here Δ can be the thickness of graphene being 0.335 nm.

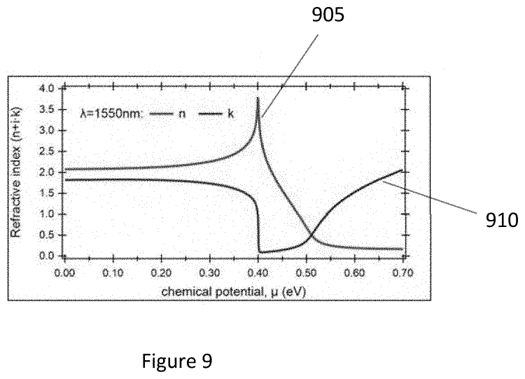

FIG. 9 shows an exemplary graph illustrating a real part (e.g., line 905) and imaginary part (e.g., line 910) of graphene complex refractive index at room temperature of 298 K according to an exemplary embodiment of the present disclosure. The refractive index of the graphene for a room temperature condition shows very strong chemical potential/doping dependence. (See, e.g., Reference 51). Thus, doping of graphene or temperature can result in changes in the electrical conductivity of graphene and thus a photocurrent.

Previous waveguide-based graphene photodetectors were based on the Si integrated photonic waveguide arrangement, where the optical mode couples to the graphene layer through the evanescence field, leading to optical absorption by graphene and a generation of photocurrent. (See, e.g., References 29-33). In this case, the photocurrent was collected by two metal electrodes located on opposite sides of the waveguide. To create a lateral metal-doped junction, either different metal electrodes have to be implemented (see, e.g., Reference 34) or an asymmetry in the electrode's distance from the waveguide have to be introduce. (See, e.g., Reference 32). For the exemplary arrangement, it can be used to create a graphene-metal junction close enough to the waveguide to efficiently separate the photoexcited electron-hole pairs at zero bias. The guided mode approach can facilitate longer interaction between graphene and the optical waveguide mode than free-space illumination. Waveguide-integration can facilitate an increase in the optical absorption in the exemplary photodetector beyond 2.3% and, by increasing the interaction length, 100% light can be absorbed and contribute to photocurrent. (See, e.g., Reference 33). However, as the metal electrode can be placed very close to the waveguide, it can disturb a propagating mode. (See, e.g., References 29-33). Furthermore, because of the evanescence coupling, the typical length needed to achieve complete absorption can be 60-100 μm. Thus, the target can be to increase the light absorption of graphene, and address the difficulty of extracting photoelectrons, as only a small area of the p-n junction close to the metal-graphene contact can contribute to current generation. (See, e.g., References 26 and 35).

To generate a photocurrent, the photogenerated carries exits the photogeneration region before they recombine. Assuming strong E-field and carrier saturation velocity of 5.5·10⁵ m/s at low carrier density, it can take only 0.36 ps for the carrier to travel out of the 200 nm current generation region. Thus, the photogenerated carriers have a good chance of exiting the photogeneration region, resulting in reasonably good internal efficiency within the high E-field photodetection region, although the lifetime can be short. The transit time limited bandwidth of the photodetector can be given by fₜ=3.5/2πtₜᵣ, where tₜᵣ can be the transit time through the photodetection region. Thus, a value of 1.5 THz can be obtained, which shows that a huge bandwidth that can be achieved with a graphene-based photodetector. Thus, the main challenge for realization of graphene-based photodetectors can be increasing the graphene absorption. Absorption of graphene can be improved by exploit the strongly enhanced electro-magnetic near-fields associated with LSPRs. (See, e.g., References 28, 36 and 37). LSPRs originate from the resonant coherent oscillation of a metal's conduction electrons in response to incident radiation. The resulting enhanced near-field surrounding the nanostructure can promote light absorption in the materials around them. Incident light, absorbed by plasmonic nanostructures, can be converted into plasmonic oscillations, with an enhancement of the local electric field. Such field enhancement, which can be in the area of the p-n junction formed in graphene, can result in a significant performance improvement. (See, e.g., Reference 39).

Additionally, this can be achieved by exciting SPP and then guiding it into the junction region at the contact edge with a graphene. (See, e.g., References 38-42). SPPs are surface bound waves propagating on a metal-dielectric interface and originate from the coupling of light with the metal's free electrons. SPPs can be delivered to the active region, junction at the contact edge, thus enhancing the overall absorption. The same electrode can be used as a contact and metal electrode supporting a collected and propagating mode.

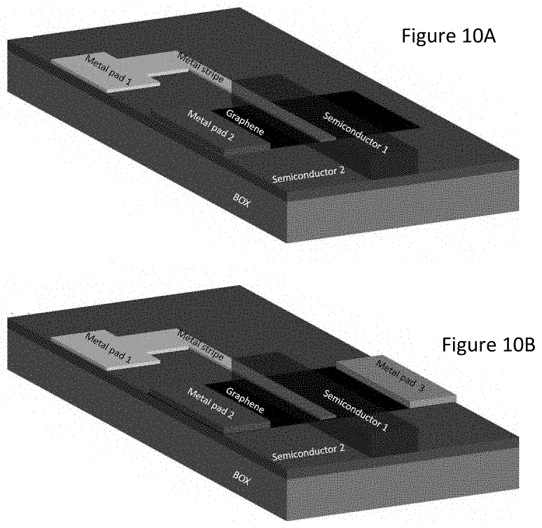

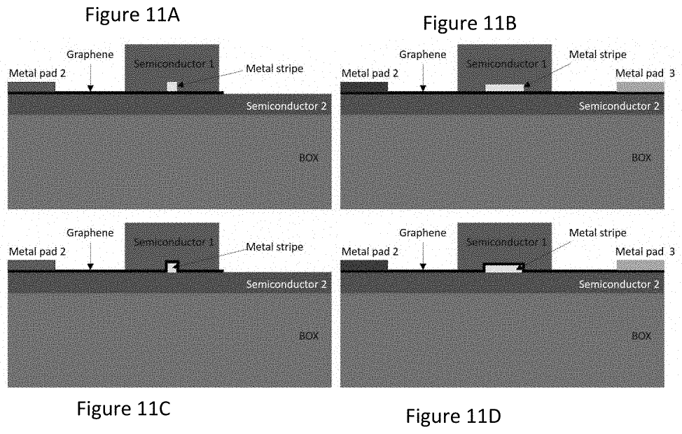

FIGS. 10A and 10B show exemplary schematic diagrams of graphene-based photodetectors according to an exemplary embodiment of the present disclosure. FIGS. 11A-11D show exemplary cross-section of a graphene-based photodetector according to an exemplary embodiment of the present disclosure. An exemplary SPP waveguide arrangement can be based on long-range dielectric loaded surface plasmon polariton waveguide (“LR-DLSPPW”) (see, e.g., References 43 and 44) with a metal stripe supported from a top by a semiconductor ridge and from a bottom by the same or other semiconductor slab. (See, e.g., diagrams shown in FIGS. 10A-11A). For the exemplary arrangement, the two SPP modes associated with two opposite interfaces can overlap and form new SPP wave with an increased propagation length. In this case, the longitudinal component of the electric field in the metal can be minimized. This can be achieved if the mode effective index above a metal stripe can be very close to the mode effective index below a metal stripe. If the mode effective index differs, the absorption in the metal stripe arises.

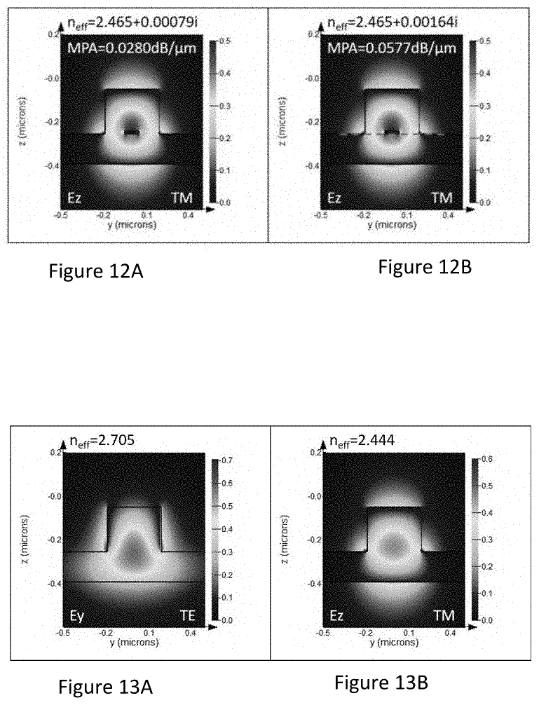

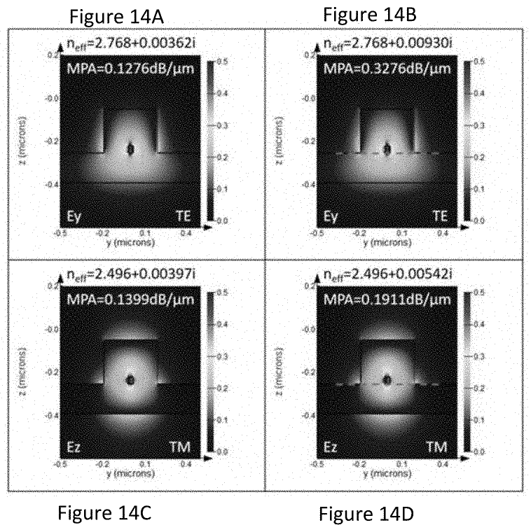

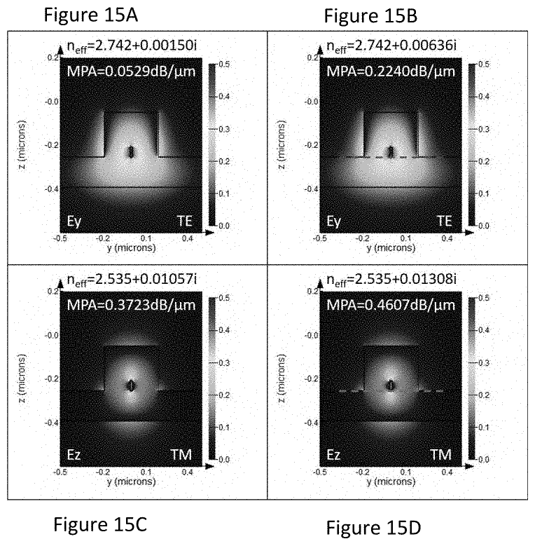

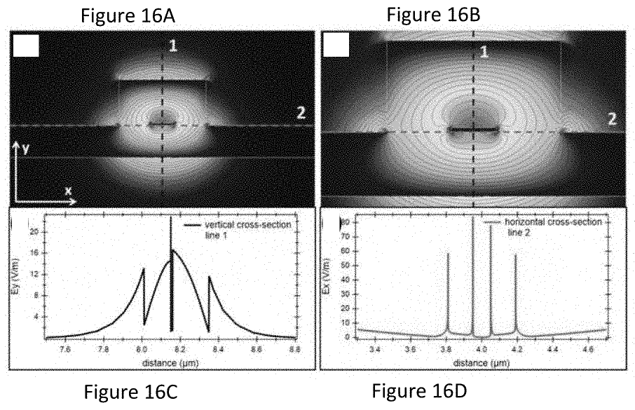

FIG. 12A shows an exemplary electric field plot of the mode with calculated mode effective index and mode power attenuation without the use of graphene according to an exemplary embodiment of the present disclosure. FIG. 12B shows an exemplary electric field plot of the mode with calculated mode effective index and mode power attenuation with the use of graphene according to an exemplary embodiment of the present disclosure. FIG. 13A shows an exemplary electric field plot of the mode with calculated mode effective index of a photonic mode for transverse electric mode according to an exemplary embodiment of the present disclosure. FIG. 13B shows an exemplary electric field plot of the mode with calculated mode effective index of a photonic mode for transverse magnetic mode according to an exemplary embodiment of the present disclosure. FIGS. 14A and 14B show exemplary electric field plots illustrating the modes with calculated mode effective indices and mode power attenuations for transverse magnetic mode for structure without graphene sheet/layer (see e.g., FIG. 14A) and with graphene sheet/layer (see e.g., FIG. 14B) according to an exemplary embodiment of the present disclosure. FIGS. 14C and 14D show exemplary electric field plots illustrating the modes with calculated mode effective indices and mode power attenuation for transverse electric modes for structure without graphene sheet/layer (see e.g., FIG. 14C) and with graphene sheet/layer (see e.g., FIG. 14D) according to an exemplary embodiment of the present disclosure. FIGS. 15A and 15B show further exemplary electric field plots illustrating the modes with calculated mode effective indices and mode power attenuations for transverse electric (TE) mode for structure without graphene sheet/layer (see e.g., FIG. 15A) and with graphene sheet/layer (see e.g., FIG. 15B) according to an exemplary embodiment of the present disclosure. FIGS. 15C and 15D show further exemplary electric field plots illustrating the modes with calculated mode effective indices and mode power attenuations for transverse magnetic (“TM”) mode for structure without graphene sheet/layer (see e.g., FIG. 15C) and with graphene sheet/layer (see e.g., FIG. 15D) according to an exemplary embodiment of the present disclosure

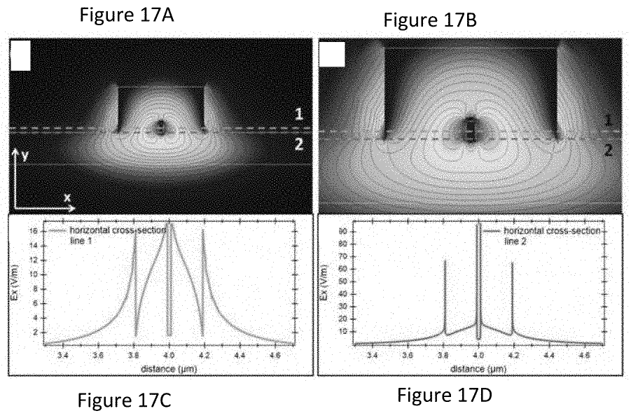

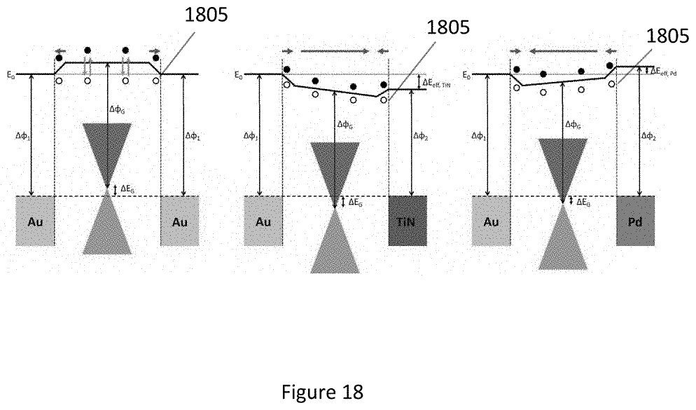

For a photodetection purpose, a graphene or 2D material can be placed either below a metal stripe or on top. A metal electrode inside a waveguide can work as a metal stripe supporting a propagating mode and as a metal electrode that can create a junction between graphene and metal. Depending on the needs, this plasmonic waveguide can support either TM or TE modes. (See, e.g., electric field plots shown in FIGS. 12A and 12B, 14A-14D, and 15A-15D). For both modes, the electric field of the modes can be located very close to the metal, with a maximum electric field located in the interface between metal and semiconductor, in the place where 2D material can be placed. Thus, an active area of the junction can be very small and close to the metal electrode ensuring very fast carrier transit time to the electrode and consequently very high operation speed. Furthermore, the responsivity that arises from a sharp metal stripe corners due to curvature induced electric-field enhancement. (See, e.g., contour plots and graphs shown in FIGS. 16A-17D) can provide further field enhancement

In particular, FIGS. 16A and 16B illustrate contour plots of the transverse magnetic mode of the exemplary waveguide according to an exemplary embodiment of the present disclosure. FIG. 16C shows an exemplary graph illustrating the out-of-plane electric field component of the propagating mode taken in the middle of the waveguide according to an exemplary embodiment of the present disclosure. FIG. 16D shows an exemplary graph illustrating the in-plane electric field component of the propagating mode taken along graphene sheet/layer according to an exemplary embodiment of the present disclosure. FIGS. 17A and 17B show exemplary contour plots of the transverse electric mode of the exemplary waveguide according to an exemplary embodiment of the present disclosure. FIG. 17C shows an exemplary graph illustrating the in-plane electric field component of the propagating mode taken in the middle of the metal stripe, above a graphene sheet/layer according to an exemplary embodiment of the present disclosure. FIG. 17D shows an exemplary graph illustrating the in-plane electric field component of the propagating mode taken at the graphene sheet/layer according to an exemplary embodiment of the present disclosure. The role of the exemplary plasmonic waveguide can therefore be to guide the incident electromagnetic energy directly to the region of the p-n junction. The second electrode can be placed very close to the waveguide without a disturbing a propagating mode that can be highly bounded to the metal stripe supporting a propagating mode. As observed (see, e.g., electric field plots and graphs shown in FIGS. 16 and 17), the in-plane electric field component of the LR-DLSPP mode, that can be beneficial in excitation of currents in graphene, can be dominant close to the graphene surface for both TM and TE supported modes and can arise from a sharp metal stripe corners.

The exemplary arrangement provides superior coupling efficiency from a photonic waveguide to a photodetector calculated at 98% for both aluminum (see, e.g., Reference 45) and gold (see, e.g., Reference 46) stripes compared to MIM gap plasmon arrangement (see, e.g., Reference 47) and inverse-DLSPP arrangements (see, e.g., Reference 48) where the coupling efficiencies were estimated at 50-60%. The improved coupling efficiency for the LR-DLSPP mode can result from the similar mode profile of the photonic and fundamental LR-DLSPP modes. (See, e.g., contour plots shown in FIGS. 12A-15D). Higher coupling efficiency means that less light radiates through coupling due to the mode mismatch (see, e.g., References 43 and 44) and more light decay in non-radiative way by interaction with the graphene, giving rise to the photocurrent generation. This improves both an external quantum efficiency and an external responsivity, which can be of interest for photodetection. As observed, the calculated mode effective index of the photonic mode (see, e.g., contour plots shown in FIGS. 13A-13D) can be very close to the mode effective indexes of the plasmonic mode (see, e.g., contour plots shown in FIGS. 12A-12D, 14A-14D, and 15A-15D) for the same waveguide parameters: Si ridge—w=380 nm, h=200 nm, Si slab—w=140 nm. Further optimization of the waveguide can achieve even better overlap.

The photodetection in the exemplary plasmonic waveguide arrangement can be achieved by photo-voltaic, photo-conductive, photo-thermoelectric, photo-bolometric or photo-gating effect and a preferred mechanism can depend on the specific design, fabrication and integration needs.

### Exemplary Photovoltaic Effect

Photovoltaic (“PV”) photocurrent generation can be based on the separation of photogenerated electron-hole (e-h) pairs by built-in electric fields at junctions between positively (e.g., p-type) and negatively (e.g., n-type) doped regions of graphene or between differently doped sections. The same effect can be achieved by applying a source-drain bias voltage V_{bias} producing an external electric field. This can generally be avoided in the case of graphene as it can be a semimetal, and therefore it can generate a large dark current. The built-in field can be introduced either by local chemical doping, electrostatically by the use of gates (e.g., split gates), or by taking advantages of the work function difference between graphene and a contacting metal. In the case of graphene-metal junction, the doping in the contact area can be fixed. This can typically bep-type for metals with a work function higher than that of intrinsic graphene (e.g., 4.45 eV), whereas the graphene channel can be p or n. The photocurrent direction can depend only on the direction of the electric field, not on the overall doping level.

### Exemplary Photo-Thermoelectric Effect

Hot-carrier-assisted transport can play an important role in graphene. Because of strong e-e interactions, a photoexcited e-h pair can lead to ultrafast (e.g., ˜10-50 fs) heating of the carriers in graphene. Because the optical photon energy in graphene can be large (e.g., ˜200 men, hot carriers created by the radiation field can remain at a temperature Tₑ and thus energy k_{B}Tₑ, with k_{B} the Boltzmann constant higher than that of the lattice for many picoseconds. Final equilibration of the hot electrons and the lattice can occur via the slower scattering between charge carriers and acoustic phonons. These processes can take place on a nanosecond timescale, although they can experience a substantial speed-up attributed to disorder-assisted collisions. The photogenerated hot electrons can produce a photovoltage, V_{PTE}, by the photo-thermoelectric (“PTE”) effect (e.g., Seebeck effect): V_{PTE}=(S₁−S₂)ΔTₑ, where S_{1,2} (in V·K⁻¹) can be the thermoelectric power (e.g., Seebeck coefficient) in the two graphene regions with different dopings, and ΔTₑ can be the electron temperature difference between the regions. The PTE effect can be dominate in graphene p-n junctions or in suspended graphene. Because hot electrons, rather than lattice heating, can generate the electronic response under these conditions, PTE graphene detectors can achieve high bandwidths, as in the case of PV detectors.

As discussed above, the photocurrent generation can be based on the photo-thermoelectric effect. However, the exemplary arrangement can also utilize a photo-voltaic effect, a photo-conductive effect, a photo-gaining effect, and a photo-bolometric effect.

### Exemplary Bolometric Effect

The bolometric effect can be associated with the change in the transport conductance produced by heating associated with the incident photons. A bolometer can measure the power of electromagnetic radiation by absorbing the incident radiation (“dP”) and reading out the resulting temperature increase dT. The parameters of a bolometer can be the thermal resistance Rₕ=dT/dP, which ultimately can define its sensitivity, and the heat capacity Cₕ which can determine its response time τ=RₕCₕ. Graphene can have a small volume for a given area and low density of states, which can result in low Cₕ, thus a fast device response. The cooling of electrons by acoustic phonons can be inefficient, owing to the small Fermi surface, and cooling by optical phonons can utilize high Tₑ. Thus Rₕ can be relatively high, giving rise to high bolometric sensitivity.

As this photodetection mechanism can be based on a light-induced change in conductance, instead of direct photocurrent generation, it can utilize an externally applied bias and can operate on homogeneous graphene, without the need to introduce a p-n junction. The conductance change induced by the incident light can be due to two mechanisms: (i) a change in carrier mobility due to the associated temperature change, or (ii) a change in the number of carriers contributing to the current. The two can coincide with the PV effect, with the electric field generated by the external bias.

Two mechanisms result in bolometric photocurrents with opposite sign; the photoinduced excess carrier induces an enhancement of the conductance, whereas the temperature dependence of the mobility leads to a reduction of the conductance. By changing the energy Fermi level E_{F}, which mechanism dominates can be controlled. Near the Dirac point, where the carrier density can be lowest, PV effects dominates, whereas far away PTE effects dominate. (See, e.g., Reference 7).

### Exemplary Photogating Effect

The photogating process can be associated to a light-induced change of the carrier density Δn of a conductor, therefore of its a. For graphene, this change in σ can be given by the relation: Δσ=Δn·e·μ. Under the optical illumination, the absorption process can lead to the generation of e-h pairs. It can induce a conductance modulation through photoinduced gate voltage. Thus, compared to the bolometric effect, which can be based on the change in carrier mobility due to heating, the photogating effect can be based on a light induced change in the carrier's density.

Compared to the previously reported waveguide arrangements (see, e.g., References 29-33), a 2D material can be placed in the maximum electric field of the mode, thus the interaction of a mode's electric field with a 2D material can be much stronger. (See, e.g., electric field plots and graphs shown in FIGS. 16A-17D). High energy e-h pairs can be created that can lead, through the e-e scattering, to the creation of multiple e-h pairs with lower energy that can still however be collected by the metal electrode that, simultaneously, can support a propagating mode. The carrier multiplication in graphene can increase the quantum efficiencies above 100%. (See, e.g., Reference 30). This process can be modeled by M=1/[1−(V_{R}/V_{BD})k], where M can be the avalanche multiplication factor, V_{R} can be the reverse voltage (e.g., photoconductive mode), VBA can be the breakdown voltage at which M goes to infinity, and k can be a power coefficient that empirically acquires values between 2<k<6. (See, e.g., Reference 48).

The relaxation of photoexcited carrier to equilibrium in graphene can include three processes. In the first procedure, photoexcited carriers can lose energy through e-e and electron-phonon scattering on a ˜10 fs time scale. Subsequently, this distribution thermalizes through electron-phonon scattering toward a hot Fermi-Diract distribution, with the time scale of hundreds of femtoseconds. The hot Fermi-Diract distribution relaxes to equilibrium by e-h recombination, which can lead to plasmon emission, phonon emission, and Auger scattering on a picosecond time scale. (See, e.g., Reference 42).

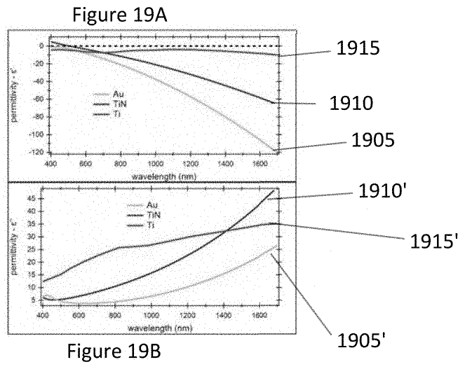

For the photovoltaic and photo-thermoelectric effects where the separation of photo-generated e-h pair by built-in field at junction between negatively (e.g., n-type) and positively (e.g., p-type) doped regions of graphene can be used, the doping can be introduced either by local chemical doping, electrostatically, by the use of two gates (e.g., split gates), or by taking advantage of the work function difference between graphene and a contacting metals. This doping can typically be p-type for metals with a work function higher than the work function of intrinsic graphene (e.g., 4.45 eV), while the graphene channel can be p or n. (See, e.g., diagrams shown in FIG. 18). In particular, FIG. 18 shows a set of exemplary band diagrams of graphene photodetectors with different sources/drains configurations according to an exemplary embodiment of the present disclosure. ϕ₁ is the work function of Au, and ϕ₂ is the work function of the asymmetric metal. E₀ is the vacuum level, and E_{F} is the Fermi level of the metal. ΔE_{G} represents the doping state of the graphene channel. The black-filled empty circles 1805 are electron holes generated by the light absorption. ΔE_{eff} is the difference in the effective work functions of the metals used for source and drain. Because of the internal potential generated by the work function difference of both metal contacts, the photocarriers can be more efficiently collected with the asymmetric metal contacts.

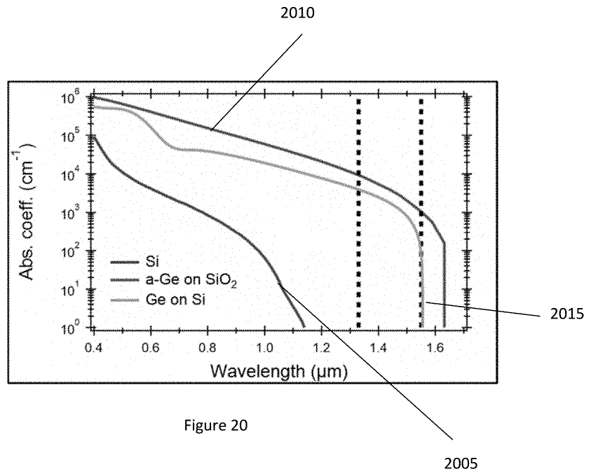

As shown in FIG. 18, for gold, a p-doped region of graphene is introduced as a work function, where Au can be 5.3 eV while for the TiN it can introduce an n-doped region of graphene as a result of lower work function of TiN (e.g., 4.3 eV) compared to the graphene. The work function of TiN can be very close to the Ti; however, TiN shows much better plasmonic properties (see, e.g., graphs shown in FIGS. 19A and 19B); thus, except Pd, each of the metals presented in this diagram can works as a metal electrode supporting a plasmonic mode. In particular, FIG. 19A illustrates an exemplary graph of the wavelength dependent real part of permittivity of Au 1905, TiN 1910, and Ti 1915 used by the exemplary waveguide according to an exemplary embodiment of the present disclosure. FIG. 19B shows an exemplary graph of the wavelength dependent imaginary part of permittivity of Au 1905′, TiN 1910′, and Ti 1915′ used by the exemplary waveguide according to an exemplary embodiment of the present disclosure. TiN belongs to the new group of the materials called transition metal nitrides (“TMN”) that in the last few years showed promise to replace a common metals such as gold, silver, copper and aluminum in the plasmonic field. They exhibit gold-competitive optical properties that can be modified during fabrication process while also offering thermal and chemical stability and compatibility with CMOS technology.

In the exemplary waveguide arrangement, a strong potential gradient located close to a metal stripe/electrode overlaps with the LR-DLSPPWs mode while there can be the absence of an overlap between the optical field and potential difference created by the second electrode. (See, e.g., electric field plots and graphs shown in FIGS. 16A-17D). The mode can be highly confined to the metal stripe, and additionally, to the ridge. It can ensure the acceleration of electrons (e.g., or holes) only in one direction and the absence of cancellation in the net photocurrent. The in-plane electric field component of the calculated modes TM and TE can be very strong on the graphene with the maximum located at the metal-graphene interface. The decay length of the in-plane electric field component on the graphene can be extremely small being in the range of a few nanometers. This can ensure extremely short transit time of the excited carriers to be collected by the metal electrode. Simultaneously, it can facilitate the collection of almost all of the carriers from graphene even taking into account the very short lifetime of photogenerated carriers. It can improve an internal efficiency as a result of extremely small active area of the photodetector that can be reduced to tens of nanometers.

As shown in from FIGS. 12A-12D, 14A-14D, and 15A-15D, most of the power in the presented configuration can be absorbed by a graphene sheet placed below a metal stripe. For a wide metal stripe and TM supported mode (see, e.g., diagrams shown in FIGS. 12A-12D) a presence of graphene contributes to more than a half of the power absorbed by a graphene. For a narrow metal electrodes supporting a TE mode, this contribution can increase. An absorption of the mode with graphene below a metal stripe increases over 4 timer from MPA=0.053 dB/μm to MPA=0.224 dB/μm compared to the same structure but without a graphene sheet.

Compared with a metal electrode placed on top of the waveguide (see, e.g., Reference 41) where metal electrode contributed for most of the power absorbed by a Si waveguide, the exemplary waveguide can achieve superior guiding properties of the mode even with a metal electrode placed inside a waveguide, in the maximum electric field of the propagating mode. This becomes even clearer when propagation lengths of the modes are compared. For a structure with metal on top of the Si waveguide (see, e.g., Reference 41), the propagation length reduced to 7 μm for wider electrodes, while in the exemplary arrangement it reached 156 μm for wide metal electrodes supporting a TM mode (see, e.g., contour plots shown in FIGS. 12A and 12B). Even for a narrow metal stripes (see, e.g., contour plots shown in FIGS. 15A-15D) supporting a TE mode it exceeds 82 μm.

Increased absorption on the metal stripe that can be at the same time on one of the photodetector's contacts, leads to a temperature rise on the metal stripe, thus heating the p-n junction at the contact edge, and producing a thermoelectric contribution to the photovoltage. Considering gold's (e.g., 300 W/mK) and graphene's (e.g., up to 5000 W/mK) thermal conductivities, the heat can be transported to the p-n junction from within the metal stripe, leading to a temperature gradient across the device and producing a thermoelectric contribution to the photovoltage. (See, e.g., Reference 40).

As shown in FIGS. 14A-14D, the field parallel to the graphene (e.g., TE mode) can be better absorbed by graphene compared to the perpendicular field (e.g., TM mode) leading to enhanced optical absorption in graphene. The strong absorption leads to the generation of more hot-carriers in graphene. This can lead to the conductance change, and the resistivity of the graphene sheet (e.g., bolometric effect). The photoinduced excess carriers can induce an enhancement of the conductance. If a bias voltage can be applied between metal pad 1 and metal pad 2 or between metal pad 2 and metal pad 3, the change of resistivity can be detected by a change of current flowing through the graphene sheet.

The second mechanism that can contribute to the bolometric effect can be based on a change in carrier mobility due to the temperature change through a heating. As shown in FIGS. 12A-12D, 14A-14D, and 15A-15D, the light can be absorbed in graphene and a metal stripe as well. When light can be absorbed by a metal stripe, it dissipates in any material that can be in contact with it. As the thermal conductivity coefficient of graphene can be much higher compared to any materials surrounding a metal stripe, most of the heat can dissipate through graphene, giving rise to a temperature increase in graphene. This leads to a change in carrier mobility due to the temperature change. Compared to the photoinduced excess carriers, the temperature dependence of the mobility can lead to a reduction of the conductance as stated above in a paper. Thus, depending on the plasmonic waveguide arrangement, one of the two mechanisms of a bolometric photocurrent generation can be implemented. Previous studies showed that integration of graphene at the top of the waveguide with metal nanoantennas deposited on top of the graphene facilitates the focus of the optical energy in the nano-gaps leading to an enhanced absorption in graphene. (See, e.g., Reference 49) For such an arrangement, the responsivity of 0.5 A/W was measured with a bandwidth exceeding 67 GHz. Compared to this arrangement, the exemplary graphene-based photodetector can take an advantage of graphene placed in the maximum electric field of the propagating plasmonic, thus the interaction of the graphene with the mode can be much stronger. Furthermore, it provides easier fabrication as there may not be a need to fabricate additional nanoantennas of top of the waveguide and control the gap between them. Simultaneously, one of the metal electrodes can be part of the plasmonic waveguide, while the second one can be placed very close to the LR-DLSPP waveguide without disturbing a propagating mode. The gapless character of graphene can facilitate optical interband transitions to occur over an ultra-wide wavelength range, unmatched by any other material. Thus, a high bandwidth can be achieved, even beyond hundreds of gigahertz. Photoexcited carriers/hot electrons can contribute to an additional photocurrent generation through a photo-thermoelectric effect, as a result of temperature difference between the two graphene regions with different dopings.

The exemplary geometry of the exemplary arrangement facilitates a realization of ground-source-ground configurations as well as a doubling of the total photocurrent as compared to the simple ground-source case, where the source electrode can be at the same time a metal stripe supporting a propagating LR-DLSPP mode. Compared to the previous configurations (see, e.g., Reference 41) with the metal electrode placed on top of the photonic waveguide, the exemplary metallic source electrode can be a part of the waveguide supporting the LR-DLSPP mode. The source electrode placed on top of the photonic waveguide can be close to the photonic's mode electric field to dope a graphene channel, however when it can be placed in close proximity to the waveguide, it can induce light absorption that can degrade device performance significantly. (See, e.g., Reference 41). In the exemplary arrangement, the source electrode simultaneously can be part of the waveguide, and can be placed in the maximum of the mode's electric field, and does not disturb the propagating mode.

Unlike previous waveguide-integrated graphene photodetectors, the metal electrode that can be a part of the LR-DLSSPW mode can facilitate independently tune graphene Fermi level and electric field across the waveguide mode in the source-drain-gate electrode arrangement where metal pad 2 serve as a source, metal pad 3 as a drain, and metal stripe, metal pad 1, as a gate. (See, e.g., diagram shown in FIG. 10B). (See, e.g., Reference 50).

As the photogenerated carrier in graphene can have very high mobility, the photodetection speed is not limited by the transit time of the carriers, but rather by the RC characteristic of the photodetector. Small metal electrodes can contribute to the small capacitance enhancing a photodetector speed. Furthermore, a small photodetector footprint can facilitate a response speed of hundreds of GHz. Moreover, graphene's two-dimensional nature can enable the generation of multiple electron-hole pairs for high-energy photon excitation. High in-plane electric field component on the graphene can generate such pairs giving rise to the carrier multiplication process even without external bias.

A waveguide-integrated plasmonic graphene photodetector in an exemplary arrangement can combine advantages of compact size, zero-bias operation, and ultrafast response over a broad range of wavelength and can enable novel architecture for on-chip communications. Together with a high coupling efficiency of a light coupling from a photonic waveguide to the photodetector, LR-DLSPPW, it facilitates very high external quantum efficiency and, in consequence, very high external responsivity.

### Exemplary Waveguide-Integrated Photodetector

Compared to lasers and modulators that can be combined into one device element, thus avoiding in the optical link, photodetectors can be elements that cannot be replaced. Such photodetectors convert light into an electrical signal, making it essential for integrating small but slow electronic components with fast but large sized photonic elements. Furthermore, these photodetectors can be the last elements in the optical link, so they can operate effectively under low input power. (See, e.g., References 52-56). The optical energy received at a photodetector can be directly related to transmitter optical output power and the total link loss. Thus, for 10 fJ/bit transmitted optical energies, the received optical energy can be 1 fJ/bit. (See, e.g., References 54 and 56). Therefore, minimizing the optical losses at the photodetector can be beneficial for the overall performance of the system. Photodetectors usually operate on the basis of the photoelectric effect, or exhibit an electrical resistance dependent on the incident radiation. The operation principal can be based on the absorption of photons and the subsequent separation of photo-generated charge carriers—electron-hole (“e-h”) pairs. They suffer, however, from low efficiency either because the photon's energy at telecom wavelengths (e.g., 0.79-0.95 eV) may not be sufficient to overcome the Si bandgap (e.g., 1.12 eV), a low detection area in the case of Ge-based photodetectors (e.g., bandgap 0.67 eV), or fabrication problems in the case of graphene-based photodetectors. (See, e.g., References 52-56). To overcome some of these problems, much attention in recent years has been focused on plasmonics-based photodetectors.

Plasmonics photodetectors are attractive because they have the ability to confine light below the diffraction limit, facilitating light-matter interaction on a deep sub-wavelength scale. (See, e.g., Reference 57). This can facilitate considerable shrinking of device size, which brings the technology one step closer to the fusion of optical and electronic components of the same size. Plasmonics can serve as a bridge between photonics and electronics by providing components with sizes similar to electronics and speeds characterized by photonics. (See, e.g., References 58 and 59). As with all other plasmonic devices, plasmonic photodetectors naturally include metallic elements that can either constitute the absorber in hot-carrier devices, or provide enhancement of the electromagnetic field inside an absorber or both. (See, e.g., References 55 and 57). Waveguide-integrated photodetectors can be beneficial for on-chip optical communication as they can be monolithically integrated with electronics. Furthermore, such devices can be placed at the terminal end of a waveguide and can utilize one of the photo detection [illegible]. (See, e.g., Reference 57). As the carrier collection path and the light propagation direction can be orthogonal in this type of photodetector, the trade-off between bandwidth and responsivity can be avoided. Additionally, they can provide a significant advantage in terms of noise reduction that scale directly with the photodetector active volume that can be kept small for a single-mode operation. (See, e.g., Reference 56).

### Exemplary Plasmonic Photodetectors

Recently, the surge of research in waveguide-integrated plasmonic photodetectors has produced results that show very promising performance improvements. In plasmonic photodetectors relying on a hot carrier photodetection schema, a bandwidth of 40 GHz and a responsivity of 0.12 A/W at 1550 nm was measured at a bias voltage of 3.5 V in a MIM waveguide arrangement with a footprint below 1 μm2. (See, e.g., Reference 60). Another exemplary arrangement relies on the inverse DLSPP waveguide design where a responsivity of 0.085 A/W at 1550 nm wavelength was measured. (See, e.g., References 61 and 62). However, by placing a graphene sheet between the metal and the semiconductor, it can be possible to enhance the efficiency of internal photoemission due to a prolonged carrier life-time in the graphene. Thus, a responsivity improvement of 0.37 A/W at 1550 nm wavelength was achieved. (See, e.g., Reference 63). Further improvements have been predicted for a thin metal stripe placed entirely inside a semiconductor and operating based on a LR-DLSPP waveguide arrangement. (See, e.g., Reference 64). Taking advantage of this arrangement, a responsivity exceeding 1 A/W was predicted while still keeping bandwidth above 80 GHz. In addition, it has been shown that by replacing noble metals with a TiN as a metal stripe, the improvement in terms of the signal-to-noise ratio (“SNR”) was predicted as a result of an optimum Schottky barrier height of 0.697 eV. Similar to the inverse-DLSPP, further improvement can be possible by placing graphene below or above a metal stripe in LR-DLSPP arrangements.

Additionally, interest has grown in graphene-based photodetectors that can operate based on PTE, photovoltaic (“PC”) or bolometric effects. (See, e.g., References 65 and 66). Each of these mechanisms can become dominant in different photodetector configurations. Recent work on plasmonic graphene photodetectors utilizing a bolometric effect showed a responsivity of 0.5 A/W at 1550 nm operating at 100 Gbit/s. (See, e.g., Reference 67). Another study utilized a narrow asymmetric MIM plasmonic waveguide to provide enhanced light-graphene interaction and enable effectively separate photo-generated carriers. (See, e.g., Reference 68). In this case, the responsivity was 0.36 A/W with bandwidth exceeding 110 GHz. In the similar, but symmetric, MIM arrangement, another group was able to measure a responsivity of 0.35 A/W and 0.17 A/W for bolometric and photovoltaic effect, respectively. (See, e.g., Reference 69). To achieve a responsivity of 0.35 A/W, a bias voltage of only 0.2 V was utilized. (See, e.g., Reference 69).

The ideal waveguide-integrated photodetector can have high responsivity (e.g., quantum efficiency), fast response time, and reduced power consumption, defined by the voltage utilized to achieve high responsivity. Furthermore, such device can be implemented into the process flow of photonic foundries. State-of-the-art waveguide-integrated photodetectors need to be at least comparable with available Ge photodetectors that offer a responsivity of 1 A/W at an operating wavelength of 1550 nm. Finally, the bandwidth can exceed 50 GHz, and a device can be CMOS compatible.

### Exemplary Germanium Photodetectors Overview

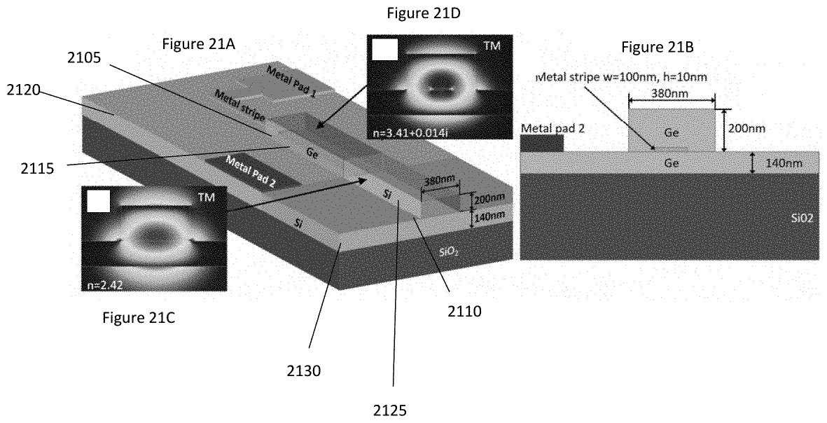

Germanium is used in a MSM configuration as it is compatible with the CMOS process, and it is a good active material for photodetection in the telecom wavelength range. (See, e.g., References 55, 57, 70 and 71). Germanium belongs to the same group IV materials as Si, so it can be easily integrated with silicon platforms. Compared to Si, which has a relatively large bandgap of 1.12 eV corresponding to an absorption cutoff wavelength of 1100 nm, Ge has a direct bandgap of 0.8 eV, which is only 0.14 eV above the dominant indirect bandgap (e.g., 0.66 eV), providing a much higher optical absorption in the 1300-1550 nm wavelength range. (See, e.g., graph shown in FIG. 20). In particular, FIG. 20 shows an exemplary graph illustrating absorption coefficients of Si (e.g., line 2005), Ge on Si (e.g., line 2010) and Ge on Sio2 (e.g., line 2015) in wavelengths of 400-1700 nm according to an exemplary embodiment of the present disclosure. This characteristic makes Ge-based photodetectors beneficial for Si photonic integration. (See, e.g., Reference 56). Additionally, while compound semiconductors possess the advantage of higher absorption efficiency and higher carrier drift velocity, they suffer from integration problems with silicon platforms, increased complexity, and the potential introduction of doping contaminants into Si CMOS devices. (See, e.g., Reference 56). Thus, Ge is the more popular material for integration with Si platforms. (See, e.g., Reference 56).

Conventional Ge waveguide photodetectors utilize deposition of metal contacts on Ge. This process, however, introduces a significant losses what influence device responsivity. (See, e.g., References 72-74). To reduce these losses, modified Ge PIN waveguide photodetectors were introduced that exploited lateral Silicon/Germanium/Silicon (“Si/Ge/Si”) heterojunctions. (See, e.g., References 72-74). These results were achieved through improved optical confinement in the Ge layer, yielding a reduction of optical loss in doped contacts. However, the difference in refractive index between doped Si and intrinsic Ge regions can still be small, which makes the mode relatively large. As a consequence, for a Ge width of w=0.3 μm, the fraction of optical power inside Ge can be estimated to be 54%, while the fraction of optical power inside doped Si can be 32%. (See, e.g., References 72 and 73). To achieve more power inside Ge, the width of Ge has to be increased. Accordingly, for a Ge width of w=1 μm, around 86% of optical power stays inside the Ge while only 8% of power is situated in the highly doped Si regions. (See, e.g., References 72 and 73). For a device with Ge width of w=1 μm and a photodetector length of 10 μm, the device responsivity was measured to be 0.5 A/W, which is in agreement with calculations showing 0.63 A/W. (See, e.g., Reference 72). For a photodetector length of 40 μm, responsivity was measured at 1.2 A/W under low reverse bias voltage of −1 V. (See, e.g., Reference 72). However, for a Ge width of 1 μm, the bandwidth barely reaches 30 GHz under even a high voltage of −3 V, and it can be independent of the device length as the frequency response can be limited by the carrier transit time. (See, e.g., References 72 and 73). In order to achieve a higher bandwidth, the Ge width needs to be reduced. Combining these results, a 50 GHz bandwidth has been obtained at a reverse bias voltage of 2 V for a Ge width of 0.3 μm and at 3 V for a Ge width of 0.5 μm. (See, e.g., Reference 73).

To enhance the electric field in the Ge, an exemplary MIM plasmonic waveguide has been introduced where the electric field can be highly enhanced in the slot between the two metals. (See, e.g., Reference 75). Compared with other SPP waveguide arrangements, the MIM fundamental mode does not exhibit a cut-off, even for very small thicknesses of semiconductor layer. Thus, an extremely small mode much below the diffraction limit can be obtained. However, as the gap size reduces, the energy begins to enter the metallic layer, reducing the mode propagation length due to an increase in field localization to the metal-semiconductor interface. As a result, absorption in the metal takes place. Thus, to minimize the losses related to absorption into the metal, it can be desired to operate a photodetector in the regime where the absorption in the Ge can be high. Therefore, absorption in the Ge can dominate over absorption losses in the metal. The resulting internal quantum efficiency (“IQE”) can be estimated to be 36% for 1310 nm wavelength and dropping below 10% for the wavelength of 1550 nm. However, to achieve even such results, a very large voltage exceeding 10 V can be utilized. As the MIM field can be confined in a narrow Ge region, 100-200 nm, short drift paths for photogenerated carriers can be achieved, producing a high speed photoresponse exceeding 100 GHz. (See, e.g., Reference 75).

### Exemplary Long-Range Dielectric-Loaded SPP Germanium Photodetectors

To evaluate the performance of the exemplary plasmonic waveguide in terms of applications for a germanium photodetector, the propagation length and mode field confinement can be considered. The former provides information how long the mode can be transmitted, for example, absorption losses into a metal, and the latter determines the electric field strength inside a waveguide, for example, interaction between a mode and material.

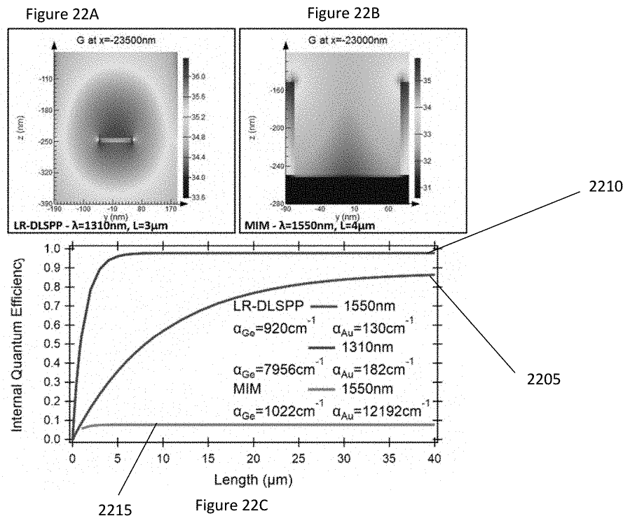

FIG. 21A shows an exemplary schematic diagrams of the exemplary Ge LR-DLSPP photodetector arrangement according to an exemplary embodiment of the present disclosure. FIG. 21B shows an exemplary diagram illustrating the cross-section of the exemplary Ge LR-DLSPP photodetector arrangement according to an exemplary embodiment of the present disclosure. FIG. 21C shows an exemplary electric field plot of the mode with the calculated mode effective index for a Si photonics rib waveguide according to an exemplary embodiment of the present disclosure. FIG. 21D shows an exemplary electric field plot of the mode with calculated mode effective index of the exemplary Ge LR-DLSPP waveguide arrangement according to an exemplary embodiment of the present disclosure.

The exemplary photoconductive germanium photodetector can be based on the absorption of a LR-DLSPP mode (See, e.g., References 76 and 77) propagating in a germanium waveguide 2105. (See, e.g., diagrams and electric field plots shown in FIGS. 21A-21D). According to this exemplary embodiment of the present disclosure, the butt-coupling arrangement can be used to couple a light from the LR-DLSPP Si waveguide 2110 (which can include a ridge 2125 and a slab 2130) to the LR-DLSPP Ge photodetector (See, e.g., diagram shown in FIG. 21A) as it can yield the lowest insertion loss. (See, e.g., References 76 and 77). However, as such a coupling arrangement can be challenging in terms of a fabrication process, a vertical evanescence coupling schema can be considered. (See, e.g., Reference 75). Since the optical energy can be perfectly confined inside the Ge waveguide 2105, efficient photodetection process can take place. By applying a bias voltage between the two metallic contacts (e.g., metal pad 1 and metal pad 2), an electric field can be generated in the Ge. Thus, the generated e-h pairs can be efficiently separated and strongly accelerated by the applied field. These separated carriers can drift toward metallic contacts, generating a photo-induced current proportional to the intensity of the optical signal. In the exemplary arrangement, the metal stripe supporting a propagating mode can be placed between the Ge ridge 2115 and the Ge slab 2120 (See, e.g., contour plot shown in FIG. 21B) where the dimensions of ridge and slab can be chosen to keep both superior mode field confinement and minimum absorption losses in the metal stripe.

LR-DLSPP inherits the advantages of a very long propagation length from LR-SPP waveguides and superior mode confinement from DLSPP waveguides. (See, e.g., References 76-79). LR-DLSPP can include of a semiconductor ridge deposited on top of a thin metal stripe/electrode, which can be supported by another semiconductor slab beneath. The entire structure can be supported by a low refractive index substrate which can facilitate mode confinement to the semiconductor ridge and underlying semiconductor slab. Due to the thin metal film, the SPPs on the two metal-semiconductor interfaces can couple to each other and form supermodes with symmetric and anti-symmetric transverse components. The symmetric mode and long-range mode can be characterized by a low longitudinal component of the electric field in the metal, thus lowering absorption losses. The long propagation distance can be achieved when the effective mode refractive indices on both metal-semiconductor interfaces can be close in value to each other such that they can couple together to minimize the electric field in the metal. Thus, the exemplary LR-DLSPP configuration facilitates high propagation length and reasonable mode confinement. In comparison, a gap SPP MIM can support a very high confined SPP mode but absorption losses from the metal arises, limiting the propagation distance to tens of the corresponding mode's wavelengths. The exemplary LR-DLSPP waveguide facilitates superior mode field confinement and high propagation length. (See, e.g., References 76-79). It has the highest evaluated FoM among all other plasmonic waveguides, taking into account mode size, wavelength, and propagation length. (See, e.g., Table 2 below). For example:

$$FoM = {L}_{p}^{2} \frac{{λ}_{0}}{{n}_{{effw}_{0}^{3}}} \qquad ( 5 )$$

where w₀ can be the lateral mode width, Lₚ can be the mode propagation length, n_{eff} can be the mode effective index, and λ₀ can be the excitation wavelength.

The FoM for LR-DSLPP can be at least two orders magnitude higher than other plasmonic waveguide configurations. (See, e.g., Table 2 below). (See, e.g., References 58, 77 and 80). Recently, another plasmonic waveguide was introduced, the so-called hybrid photonic-plasmonic waveguide, which offers extremely long propagation length. However, the mode confinement exceeds 7 μm so it may not be practical for on-chip integration. (See, e.g., Reference 80). Furthermore, the FoM for this waveguide exceeds other plasmonic waveguides, but it still over 30 times lower compared to the LR-DLSPP waveguide. Thus, in terms of the absorption losses into metal, mode field confinement, and possible integration with other on-chip components, the exemplary LR-DLSPP waveguide can be a perfect candidate for photodetection applications.

TABLE 2
FoM for plasmonic waveguides.

| | Waveguide | | | | | |
|---|---|---|---|---|---|---|
| | LR-DLS | LR-SPP | DLSPP | Gap (MIM) | | HPP |
| FoM | 3.2 · 10⁶ | 3.2 · 10⁴ | 3.4 · 10³ | 1.1 · 10⁴ | 2.9 · 10⁴ | 1.0 · 10⁵ |

The exemplary LR-DLSPP mode profile matches the mode of the photonic waveguide, facilitating efficient coupling between photonics and plasmonic platforms. (See, e.g., contour plots shown in FIGS. 2C and 2D). The exemplary LR-DLSPP waveguide's mode supporting a TM mode has a similar profile to the photonic TM mode fabricated based on the same material. The overlap integral between them shows up to 98% coupling efficiency with very good tolerance to the offset of the metal stripe supporting the LR-DLSPP mode. (See, e.g., References 78 and 79).

The exemplary LR-DLSPP configuration therefore demonstrates great potential for creation of photoconductive photodetectors based on germanium and other absorbing materials where superior mode confinement and low absorption losses in metal can be beneficial.

### Exemplary LR-DLSPP Waveguide for a Photodetection

In a state-of-the-art PIN photodetector, the cross-sectional area of the waveguide has to be big enough to minimize or otherwise reduce absorption losses in a doped Si, so waveguide dimensions of w=1 μm and h=260 nm can be utilized to achieve good mode field confinement in the Ge, low absorption into the doped Si, with high responsivity as a result. (See, e.g., References 72 and 73). The cross-sectional area for such a waveguide can be 0.26 μm². In contrast, the plasmonic MIM photodetector offers an extremely small cross-sectional area of 0.016 μm², although at the cost of absorption losses into the metal that significantly limit its photodetector quantum efficiency. (See, e.g., Reference 75). Calculations show that the quantum efficiency of a MIM photodetector operating at 1310 nm does not exceed 70%, and drops to 30% for 1550 nm. For the MIM photodetector with Ge between the metals and on top of the MIM structure, the quantum efficiency does not exceed 10%.

Compared to the MIM structure, the exemplary Ge photodetector based on the LR-DLSPP waveguide arrangement provides a cross-sectional area of 0.129 μm² even when far from optimization. Such a cross-section was chosen to facilitate efficient coupling of light from the Si waveguide to the photodetector through a butt-coupling arrangement. (See, e.g., diagrams and contour plots shown in FIGS. 21A-21D). The exemplary Ge plasmonic photodetector can be an extension of the Si waveguide, facilitating efficient transfer of the optical power to the Ge. This can improve device performance in terms of photo-responsivity and opto-electrical bandwidth.

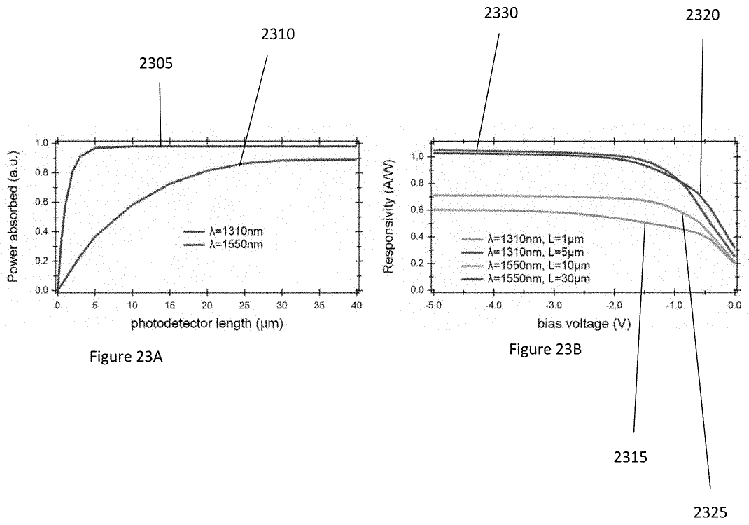

FIG. 22A shows an exemplary plot of the generation rate at the middle of the photodetector for the exemplary LR-DLSPP arrangement according to an exemplary embodiment of the present disclosure. FIG. 22B shows, for a comparison, an exemplary plot of the generation rate at the middle of the photodetector for the exemplary MIM photodetector arrangement according to an exemplary embodiment of the present disclosure. FIG. 22C shows an exemplary graph illustrating a comparison of the losses in metallic stripe/contact on quantum efficiency as a function of the device length of 1550 nm for LR-DLSPP (e.g., line 2205) and asymmetric MIM arrangements for wavelengths 1310 nm (e.g., line 2210) and 1550 nm (e.g., line 2215) according to an exemplary embodiment of the present disclosure.

The calculated electric field profile of the fundamental TM mode (See, e.g., electric field plot shown in FIG. 21D) occupies almost the entire Ge area. Thus, the electron-hole pairs can be generated in almost the entire Ge area with most of the electron-hole pairs generated close to the metal stripe that serves simultaneously as one of the electrodes. (See, e.g., generation rate plot shown in FIG. 22A). As a result, a quantum efficiency of 97% can be achieved with a wavelength of 1310 nm even for a very short photodetector length of 5 μm. (See, e.g., graph shown in FIG. 22C). Furthermore, compared to the MIM plasmonic photodetector (See, e.g., generation plot shown in FIG. 22B) that yields quantum efficiencies up to 30% even for a 40 μm long photodetector operating at 1550 nm, the exemplary LR-DLSPP waveguide can achieve a quantum efficiency as high as 84% for a 30 μm long photodetector operating at the same wavelength of 1550 nm.

### Exemplary Quantum Efficiency of the LR-DLSPP Ge-Based Photodetector

Neglecting the scattering losses, the responsivity and the IQE of a photodetector can depend only on the absorption coefficient of Ge, α_{Ge}, and metal, αₘ:

$$IQE = \frac{{α}_{Ge} {L}_{GE}}{{α}_{Ge} {L}_{Ge} + {α}_{m} {L}_{m}} ( 1 - exp ( - ( {α}_{Ge} {L}_{Ge} + {α}_{m} {L}_{m} ) ) ) \qquad ( 6 )$$

where L_{Ge} and Lₘ can be the total length of the Ge waveguide and metal contact, respectively. Here L_{Ge}=Lₘ. The absorption of Ge and the confinement factor of the mode in the Ge waveguide can determine α_{Ge}. Also, the overlap of the mode with the metal can determine αₘ. (See, e.g., Reference 58). To calculate the absorption coefficients of metal (e.g., Au), α_{Au}, and Ge, α_{Ge}, 3D FDTD and FEM simulations were performed. To determine α_{Au}, the Ge absorption coefficient was set to 0 and the Au stripe/electrode (See, e.g., diagrams and contour plots shown in FIGS. 21A-22C) was described by a complex refractive index. The reduction in the transmission amplitude through the LR-DLSPP waveguide was assigned to absorption by the Au stripe/electrode. Thus, an effective absorption of Au stripe/electrode, α_{Au}, was calculated to be α_{Au}=130 cm⁻¹ and α_{Au}=182 cm⁻¹ for wavelengths of λ=1550 nm and λ=1310 nm (See, e.g., graph in FIG. 22C). In order to obtain α_{Ge}, the absorption coefficient of Au was set to 0, and Ge was described by a complex refractive index, so the losses were assigned to the absorption of the Ge waveguide.

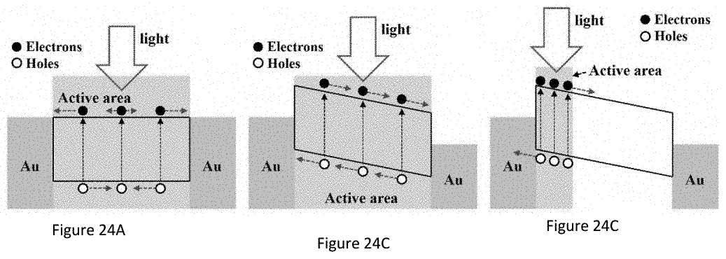

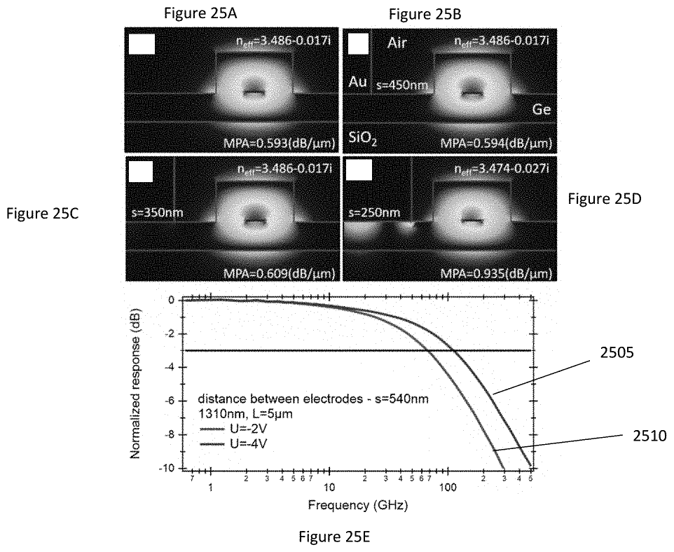

The calculated effective absorptions of Ge was α_{Ge}=920 cm⁻¹ and α_{Ge}=7956 cm⁻¹ for wavelengths of λ=1550 nm and λ=1310 nm (See, e.g., graph shown in FIG. 22C). As shown in FIG. 22C, the quantum efficiencies exceed 97.7% and 86.3% for wavelengths of λ=1310 nm and λ=1550 nm, respectively. An L=24 μm long photodetector can be utilized to achieve a quantum efficiency over 80% for wavelength λ=1550 nm, while for a wavelength λ=1310 nm, quantum efficiency of 96% was possible for the L=5 μm long photodetector. In comparison, a quantum efficiency of 75% was achieved at λ=1310 nm for a L=10 μm long Germanium-on-insulator (“GOT”) MSM photonic photodetector while for λ=1550 nm it was only 20% and utilized a photodetector length of L=20 μm. (See, e.g., Reference 71). The theoretical results were compared with other plasmonic Ge photodetectors realized in the MIM plasmonic waveguide arrangement, with Ge placed in a slot of width d=120-160 nm between Au electrodes. In this configuration, a quantum efficiency of 75% was calculated for the L=10 μm long photodetector at a wavelength of λ=1310 nm, and only 30% for the L=50 μm long photodetector at λ=1550 nm. (See, e.g., Reference 75). Compared to these results, the exemplary plasmonic photodetector shows a significant improvement in terms of quantum efficiency and footprint. The smaller photodetector's footprint means a lower RC and higher operation speed of the photodetector. This can be based on good mode field confinement in the entire active area (See, e.g., contour plot shown in FIG. 22A) and minimalized losses related with the metal stripe/electrode. (See, e.g., plots shown in FIGS. 23A-23D and in FIGS. 24A-24D).

In the exemplary arrangement according to the present disclosure, the absorption coefficient of Ge, α_{Ge}, can be at least 7 times higher compared to the absorption coefficient of Au, α_{Au}, for a wavelength of λ=1550 nm, and over 43 times higher for a wavelength of λ=1310 nm where Ge shows a higher absorption. (See, e.g., graph shown in FIG. 22C). For the other arrangements discussed above (See, e.g., References 71 and 75), α_{Ge} was always lower than α_{Au}. Thus, for GOT photonic waveguides (See, e.g., Reference 71), α_{Ge} was 10 times lower compared to α_{Au} for wavelength of λ=1550 nm and almost the same for wavelength of λ=1310 nm. Similar trends can be observed for the MIM Ge photodetector. (See, e.g., Reference 75).

### Exemplary Responsivity of the LR-DLSPP Ge-Based Photodetector

The light propagating in the Ge LR-DLSPP waveguide can be absorbed mostly by the Ge and only partially by a metal. (See, e.g., graph shown in FIG. 22C). The amount of power absorbed by the metal can be almost neglected as it constitutes less than 10% of overall absorption for a wavelength of 1310 nm and less than 2.5% for a wavelength of 1550 nm. Here, it can be assumed that light can be absorbed mostly by the Ge. The absorption per unit volume can be calculated from the divergence of the Poynting vector. Thus, for example:

P_{abs}=−0.5 Re( [symbol] · [symbol] )=−0.5ω|E|²Im(ε(ω)) (7)

FIG. 23A shows an exemplary graph illustrating the total power absorbed by a photodetector for 1310 nm (e.g., line 2305) and 1550 nm (e.g., line 2310) according to an exemplary embodiment of the present disclosure. FIG. 23B shows an exemplary graph illustrating photodetector responsivity as a function of the reserve bias for wavelength of 1310 nm and a photodetector length of lμm (e.g., line 2315), wavelength of 1310 nm and length of 5 μm (e.g., line 2320), 1550 nm and length of 10 μm (e.g., line 2325), and wavelength of 1550 nm and length of 30 μm (e.g., line 2330) according to an exemplary embodiment of the present disclosure.

As a result, an absorption as a function of space and frequency can depend only on the electric field intensity and the imaginary part of the material permittivity. Performed simulations showed that 97% of the power can be absorbed in the first 5 μm of the LR-DLSPP waveguide for a wavelength of 1310 nm and over 88% of the power coupled to the photodetector can be absorbed in the first 30 μm of the photodetector for a wavelength of 1550 nm. (See, e.g., graph shown in FIG. 23A).

These exemplary results fit very well with the data shown in the graph of FIG. 22C, where the internal quantum efficiency was calculated analytically based on mode effective index calculations. As can be seen from Eq. (7), better mode field confinement provides higher electric field intensity, even for the same material, giving rise to higher power absorption. The absorbed photons can generate electron-hole pairs which can then be separated by the electric field applied to the metal electrodes, producing a photocurrent. The number of absorbed photons per unit volume can be calculated by dividing the absorbed power by the Ge by the energy per photon. Thus, for example:

$$g = \frac{{P}_{abs}}{ℏ ω} = \frac{- 0.5 {\vert E \vert}^{2} Im ( ɛ ( ω ) )}{ℏ} \qquad ( 8 )$$

The frequency-dependent photon absorption rate can be equivalent to the generation rate under the assumption that each absorbed photon can excite an electron-hole pair. The generation rate for wavelengths of 1310 nm and 1550 nm with different photodetector lengths was calculated using Lumerical FDTD simulations and then exported to Lumerical Devices, where it was used to calculate a responsivity for each photodetector configuration. (See, e.g., graph shown in FIG. 23B). Here, the values of bulk recombination, carrier life time, and surface recombination velocity at the interface between Ge and SiO₂ and surface recombination were taken from experimental data. As expected from previous calculations (See, e.g., graph shown in FIG. 22C), the photodetector length of 5 μm can be sufficient to produce a responsivity exceeding 1 A/W at 1310 nm. However, the photodetector length needed to obtain a responsivity of 1 A/W at 1550 nm wavelength increases to 30 μm. For a shorter photodetector in the range of 10 μm, the responsivity was calculated to be 0.7 A/W for 1550 nm. These values can be higher compared to previously reported results of a plasmonic photodetector based on the asymmetric MIM structure with responsivity measured in the range of 0.05-0.1 A/W at the wavelength of 1310 nm. (See, e.g., Reference 75). The exemplary calculations confirm this value where the internal quantum efficiency calculated for such a structure was below 0.1. (See, e.g., graph shown in FIG. 22C). Even assuming a perfect coupling efficiency to the photodetector, the responsivity may not exceed 0.1 A/W. (See, e.g., Reference 75). One of the reasons for a much lower responsivity can be associated with the absorption losses into the metal that particularly arises for the MIM configuration. Also, as observed in the generation rate plot shown in FIG. 22B, the photogenerated electron-hole pairs are generated mostly in the upper side of the MIM structure, with a maximum generation rate localized on both sides of the photodetector in very close proximity to the metal. By comparison, the exemplary LR-DLSPP waveguide arrangement generates carriers in the entire area occupied by the germanium waveguide. (See, e.g., generation rate plot shown in FIG. 22A). This, together with highly reduced absorption losses caused by metal, can facilitate a responsivity exceeding 1 A/W, even for a very compact photodetector.

The dark current achieved in the exemplary devices was around 0.6 μA for a 3 μm long photodetector operating at wavelength of 1310 nm. As shown FIGS. 22C, 23A, and 23B, such a length can be sufficient to achieve almost 96% internal quantum efficiency and responsivity exceeding 1 A/W. This value can be much smaller than expected from a typical MSM photodetector. This can be based on the small active area of the exemplary photodetector. Implementation of asymmetric metallic contacts (See, e.g., References 85 and 86) or a thin barrier of a large bandgap material below an external electrode can be beneficial. (See, e.g., Reference 87).

### Photodetector Speed and Bandwidth

In telecommunication systems, photodetectors can be utilized to detect optical signals modulated at high data rates. Thus, an important figure of merit can be the opto-electrical 3 dB bandwidth, which can be defined as the frequency range from DC to cut-off frequency f_{3dD} i.e., the frequency at which the electrical output power drops by 3 dB below power value at very low frequency. The opto-electronic bandwidth of a photodetector can depend both on the carrier transit time and RC response time. To reduce the carrier transit time, the distance between the collecting electrodes can be small. In comparison, RC time reduction can be obtained by lowering the contact resistance of the metal electrodes and by reducing the detector length which reduces the photodetector capacitance. (See, e.g., Reference 81). The RC-limited 3 dB cut-off frequency can be expressed as, for example:

$${f}_{RC} = \frac{1}{2 π {R}_{eff} {C}_{pd}} \qquad ( 9 )$$

where R_{eff} can be the effective overall resistance and C_{pd} can be the junction capacitance. The carrier transit time, that defines the time of photo-generated electrons or hole to travel through the active region prior to being collected by the contacts, can be estimated using, for example:

$${f}_{t} \approx \frac{3.5 v}{2 π {d}_{abs}} \qquad ( 10 )$$

where d_{abs} is the distance between the site where carriers can be generated and the electrode collecting those carriers, and v can be the average carrier velocity. (See, e.g., References 64, 81, and 88).

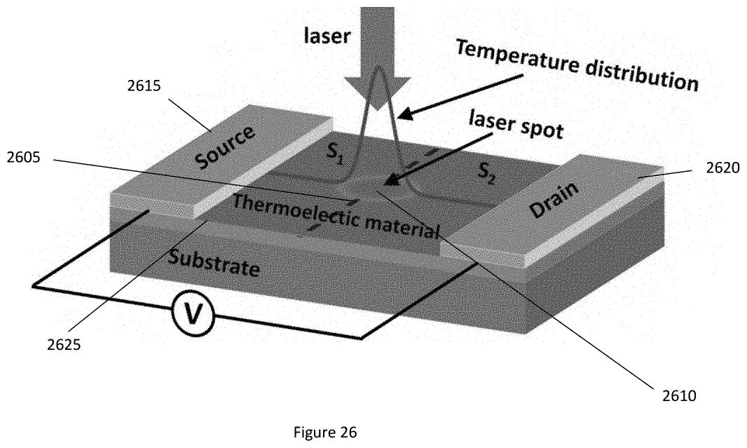

As discussed above, a L=5 μm long photodetector can be utilized to achieve a quantum efficiency exceeding 95% at a wavelength of 1310 nm. Taking into account the distance between both electrodes to be approximately 450 nm i.e., the second electrode can be placed around 300 nm from the Ge waveguide, a capacitance in the range of a few fF can be suspected. The second electrode placed 300 nm from the waveguide may not disturb a propagating mode in the waveguide. (See, e.g., contour plot shown in FIG. 25C). As a result, there can be small propagation losses, and associated with it, small absorption by the metal electrode supporting the propagating mode, giving rise to enhanced quantum efficiency and responsivity. If the device/photodetector can be connected with a 50Ω load, a RC cut-off frequency exceeding a 1 THz can be achieved.

In the exemplary design, all carriers can be generated in the area limited by the germanium waveguide. Assuming a distance between electrodes of 450 nm and a drift velocity of 6.5·10⁶ cm/s (See, e.g., Reference 88), a bandwidth of fₜ=80 GHz can be achieved. However, as it can be observed from FIGS. 4A-4D and 3A-3D, over 90% of absorbed power can be located around 100 nm from the collecting metal electrode.

Therefore, a bandwidth exceeding 100 GHz can be achieved even for an electrode spacing of 540 nm (See, e.g., contour plot shown in FIG. 25B) that corresponds to a distance of 450 nm between an external electrode and Si ridge. It illustrates the potential for the realization of high bandwidth photodetectors based on the LR-DLSPP waveguide arrangement. (See, e.g., graph shown in FIG. 25E, where line 2705 illustrates U=−2V and line 2510 illustrates U=−4V). Because of the nature of SPPs that facilitates strong light concentration in the near-field, most of the carriers can be generated in very close proximity to the metal stripe/electrode. As a result, the average photogenerated electron path length to the metal electrode can be significantly reduced in comparison to the conventional photoconductive photonic photodetectors. (See, e.g., Reference 82). Thus, the photogenerated carriers can reach a metal electrode much faster even in the case of absorbent materials with relatively low drift velocity in the semiconductor. Furthermore, a significant proportion of the photogenerated electrons can reach the contact in a sub-picosecond timescale, which improves the operation bandwidth and the exemplary photodetector's efficiency and responsivity. In conventional photoconductive photodetectors the majority of the photo-generated carriers recombine in the substrate before reaching the contact electrodes. (See, e.g., Reference 82). With the characteristics described above, the exemplary photodetector can offer a bandwidth exceeding 150 GHz.

As previously discussed, the bandwidth of the photodetector may not be limited by the RC time constant, but the transit time utilized for carriers to drift to the contact electrode collecting the carriers. By decreasing the distance between the two contacts, a very high electric field can be obtained at low bias voltage what additionally improves carrier collection.

The exemplary Ge plasmonic photodetector provides a combination of advantages and a huge flexibility in terms of design and integration with other materials. Due to the difference in velocity of the carriers, electrons and holes, the response of the photodetector can usually be asymmetric as holes can be delayed compared to electrons. However, in the exemplary LR-DLSPP photodetector arrangement, carriers can be photogenerated in the region surrounding the metal stripe that serves simultaneously as a collection electrode. (See, e.g., FIGS. 21A-21D and FIG. 24C). Consequently, the holes with lower mobility and shorter paths may only be moving to the metal stripe where they can be collected, whereas the electrons can move to the external electrode. Furthermore, the exemplary arrangement facilitates further improvement through combining it with narrow and wide bandgap semiconductors such as n-Si, so electrons can be isolated and the photoresponse of the device may only be dependent on the transport of electrons.

### Exemplary Symmetric and Asymmetric Electrodes

Compared to previous waveguide arrangements where carriers were generated in the entire area limited only by metal contacts (See, e.g., diagrams shown in FIGS. 24A and 24B) (See, e.g., References 71-75) (without a bias voltage (See, e.g., FIG. 24A) and under a bias voltage (See, e.g., FIG. 24B)), in the exemplary arrangement the carriers can be generated close to the metal electrode/contact supporting a propagating mode. (See, e.g., FIG. 24C, under a bias voltage). This results in an extremely fast transit time for carriers to reach the electrode. The metal electrodes/contacts can consist of the same metals creating a symmetric structure, or they can create an asymmetric structure when two different metals can be used. In terms of the metal electrodes supporting a propagating mode, the electrode can illustrate superior plasmonic properties defined by the real and imaginary parts of the permittivity. The real part of permittivity can be negative with as large a value as possible. Simultaneously, to minimize propagation losses related to absorption, the imaginary part of permittivity can be as small as possible in the desired wavelength range. In the last few years, a new class of plasmonic materials appeared, so-called transition metal nitrides (“TMNs”), which offer optical properties close to those of noble metals. (See, e.g., References 64, 83, and 84). Additionally, they show high temperature durability and CMOS compatibility while their optical properties strongly depend on the deposition conditions. (See, e.g., References 64, 83, and 84). As TMNs, such as for example TiN, are CMOS compatible, they can be integrated in the exemplary LR-DLSPP photodetector waveguide arrangement providing more flexibility in the design process. This can facilitate the photodetector to include asymmetric metallic contacts, where TiN can be arranged either as an external electrode (e.g., metal pad 2 shown in the diagrams of FIGS. 21A and 21B) or a metal electrode supporting a propagating plasmonic mode and connected with metal pad 1 as shown in FIGS. 21A and 21B. Furthermore, other materials with superior plasmonic properties, such as aluminum, copper, silver, gold, zirconium nitride (“ZrN”) and others, can be used as a metal stripes supporting a propagating mode. In the case of an external electrode, all materials showing good electrical properties can be implemented in the exemplary arrangement. Previous publication has discussed that asymmetric metallic contacts can minimize a dark current in the photodetector. (See, e.g., References 85 and 86). Alternatively, or in addition, a thin barrier with a large bandgap material can be added between metal contacts and germanium. (See, e.g., Reference 87).

### Exemplary Plasmonic Graphene Photodetector Based on Channel Photo-Thermoelectric Effect

### Exemplary Photo-Thermoelectric Effect

Three exemplary effects can contribute to a photodetection in waveguide-integrated graphene devices (see, e.g., References 113-116): (i) photo-voltaic (PV) or photo-conductive (PC) (see, e.g., References 117-122), (ii) photo-bolometric (PB) (see, e.g., References 123-127) and (iii) photo-thermoelectric (PTE) (see, e.g., References 128-131) effects. The choice of the effect depends on device configuration, design and operation conditions. (See, e.g., References 113, 116, 122, and 128). PTE photodetectors in recent studies showed that PTE effect dominates over PV the photocurrent generation in graphene devices. (See, e.g., References 132 and 133).

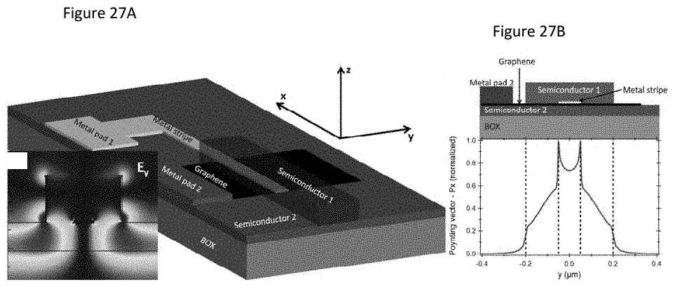

FIG. 26 illustrates an exemplary diagram illustrating the photo-thermoelectric effect under a free space illumination according to an exemplary embodiment of the present disclosure, and provides the operation principle of the PTE effect in a p-n junction 2605 where the laser spot 2610 induces a temperature gradient that results in a net thermoelectric voltage across the thermoelectric material 2625 due to the Seebeck effect. (See, e.g., Reference 134). Thus, the generated photocurrent can be proportional to the Seebeck coefficient for the two sides of the junction (e.g., source 2615 and drain 2620) and the carrier's temperature rise in a graphene. As a result, the materials with high Seebeck coefficient, which can sustain a high temperature, can be highly desired. However, most of the thermoelectric materials suffer from low melting temperatures that do not allow them to reach a high operation temperature, which can limit a performance of the PTE photodetector. (See, e.g., Reference 135). Additionally, they suffer from the relatively long response time originating from the phonon-dominated transport, which can be typically on the order of milliseconds. (See, e.g., Reference 135).

Graphene is a very attractive material for such a photodetector. Apart from the excellent properties, it can sustain a very high temperature; thus far the highest of all materials exceeding 4550 K or even 6000 K under short period of time (See, e.g., Reference 136), thus, enhancing a photocurrent. (See, e.g., Reference 135). Furthermore, the response time dominated by the phonons interaction is in the range of about 2-4 picoseconds. (See, e.g., References 137-140). The operation of such a photodetector utilizes spatially in-homogeneous doping profile that is created by local heating of p-n junction by the incident laser power. (See, e.g., References 104, 109, 128-131, and 141). As a result, the non-equilibrium hot carriers can be excited with an electron temperature Tₑ higher than that of the lattice, giving rise to the electron temperature gradient across a junction. This increases in the temperature of photoexcited carriers is a direct consequence of the large optical phonon energy in graphene (e.g., ˜200 eV) and low scattering rate of electrons by acoustic photons. (See, e.g., References 138-144). The latter give rise to an increased temperature of the photoexcited carriers for picoseconds, while the lattice stays close to room temperature. In such a photodetector, the photovoltage is generated from hot electrons through the Seebeck coefficient that varies in the graphene sheet as result of different doping or the temperature gradient. For different doping levels on both sides of the junction, and the temperature profile in the graphene, the Seebeck coefficient can vary across graphene, which can generate a photo-thermoelectric voltage. Due to the non-monotonous dependence of the difference of the Seebeck coefficient in the two different doped regions of the junction, the resulting photovoltage exhibits multiple sign reversals in dependence of the gate voltage. The characteristic 6-fold pattern is the result of the two doping levels on either side of the junction. Another approach relies on heating of one contact that can lead to a temperature gradient across a graphene channel resulting in a photo-thermoelectric contribution to the photovoltage. (See, e.g., References 128 and 144).

### Exemplary Graphene Photodetector Arrangement

The exemplary photodetector can be based on an exemplary metal-graphene-metal (“MGM”) arrangement (See, e.g., References 117, 118, and 131) with a graphene channel contacted by two electrodes, either of the same (See, e.g., Reference 118) or two different metals. (See, e.g., References 117 and 122). The difference in work function between the metal pads and graphene leads to charge transfer with a consequent shift of the graphene Fermi level that is in contact with the metal. (See, e.g., References 117, 122, and 145). As the Fermi level of the metal-free graphene channel can be different, this can result in a potential gradient between the metal-free graphene and graphene that can be in contact with metal. (See, e.g., References 117 and 122). This inhomogeneous doping profile (See, e.g., References 144 and 145) can create a junction along the channel that can be beneficial in the photodetection process, as it can result in an internal electric field capable of separating the light induced e-h pairs.

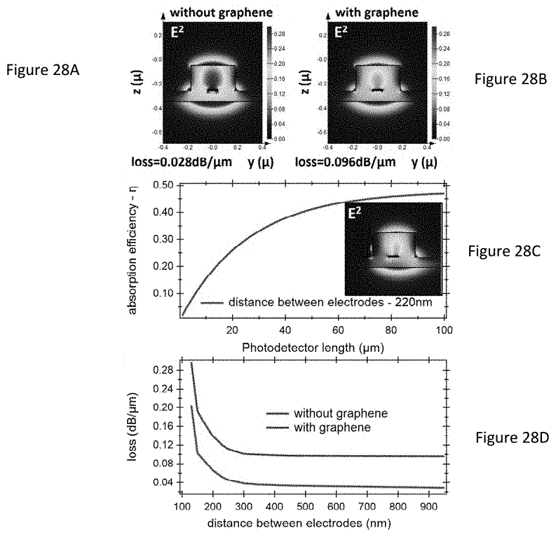

FIG. 27A shows an exemplary schematic diagram of the exemplary graphene photodetector in LR-DLSPP waveguide configuration (See, e.g., References 147-150) with a plasmonic mode guided on by a metal stripe that simultaneously serves as one of the electrodes. Here, as shown in FIG. 27A, semiconductors 1 and 2 are Si. However, it can be from any other materials—the same or different materials as long as it provides a guiding properties. FIG. 27B shows an exemplary cross-section of the exemplary graphene photodetector and an associated Poynting vector field distribution according to an exemplary embodiment of the present disclosure. The electric field of the propagating mode can be highly localized between the metal and the semiconductor that leads to enhanced light—graphene interaction for a graphene placed below metal stripe. (See, e.g., schematic diagram shown in FIG. 27B). FIG. 27C shows an exemplary contour plot of the in-plane electric field component of the LR-DSLPP mode according to an exemplary embodiment of the present disclosure. The in-plane electric field component of the LR-DLSPP mode can be beneficial for excitation of the current in graphene, which is very strong close to the graphene sheet even for the TM supported mode. (See, e.g., References 147-151). Thus, the carrier's temperature in graphene is increased.

As the electron-electron scattering in graphene can be ultrafast on the order of 10 fs, and electron-phonon scattering relatively slow on the order of picoseconds (See, e.g., References 137-140, 142, and 143), the photoinduced carriers can be thermalized by the electronic system, and can dissipate the heat very slowly to the lattice. Because of the linear electronic dispersion and its low dimensionality, the electron-electron scatterings can be substantially stronger than the electron-phonon scatterings. Typically, the cooling length of hot electrons in graphene exceeds hundreds of nanometers. Thus, the electrons in graphene may not reach thermal equilibrium with the lattice before being collected. (See, e.g., References 114 and 137-140).

In the exemplary photodetector arrangement, the electric field reaches a maximum at the interface between metal stripe and semiconductor along graphene sheet, and can decay fast in the direction of second electrode. This can lead to an asymmetric temperature distribution between metal contacts, and can be transduced into an electrical signal through the Seebeck effect. This can be beneficial in excitation of currents in graphene, the in-plane electric field component (Ey) of the LR-DLSPP mode is very strong close to the graphene surface even for TM supported mode (See, e.g., References 147-150) and arise from a sharp metal stripe corners. (See, e.g., contour plot shown in FIG. 27C). (See, e.g., Reference 151). The decay length of the Ey electric field on the graphene can be extremely small being in the range of a few nanometers. (See, e.g., FIG. 27C). This can provide an extreme temperature gradient in the graphene, which can enhance the photodetector performance.

### Exemplary Calculation of Power Absorbed by Graphene Sheet

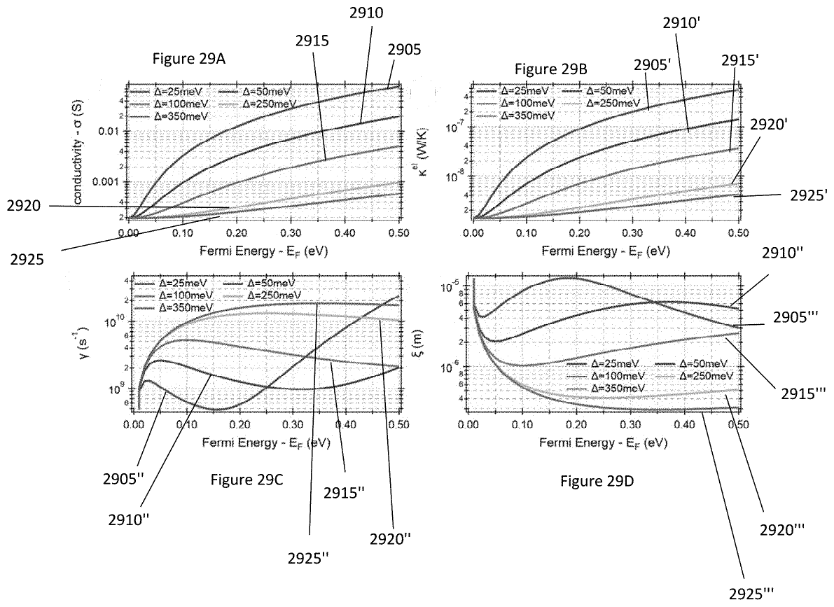

FIGS. 28A and 28B show plots of the calculated E² of the exemplary LR-DLSPP waveguide mode according to an exemplary embodiment of the present disclosure. FIG. 28C shows an exemplary graph and corresponding intensity plot of the calculated absorption efficiency versus photoelectric length for the photodetector according to an exemplary embodiment of the present disclosure. FIG. 28D shows an exemplary graph illustrating the propagation losses versus distance between electrodes for a structure without graphene and with graphene according to an exemplary embodiment of the present disclosure

To evaluate the performance of the photodetector, the amount of power absorbed by a graphene sheet needs to be calculated. Power absorbed by the graphene sheet can be calculated from, for example:

P_{abs}=Pᵢₙe^{-α·L} (11)

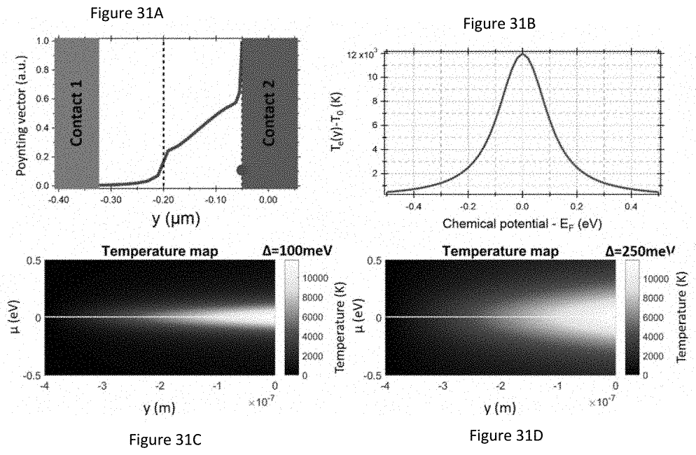

For example, around Pᵢₙ=165 μW of power coupling to a photodetector was simulated. For the absorption coefficient for graphene α_{G} and metal am obtained from a simulation, the length dependency of fraction of light absorption in graphene η can be calculated by, for example:

$$η = \frac{{α}_{G}}{{α}_{M} + {α}_{G}} ( 1 - {e}^{- {α}_{G} L} {e}^{- {α}_{M} L} ) \qquad ( 12 )$$

where L can be the length of photodetector. The results are shown in the graph of FIG. 30C. As shown in FIG. 30C, it can be deduced that for a 40 μm-long photodetector, about 40% of power can be absorbed by graphene. However, only half of this power can contribute to the photodetector performance. As a result, it can be assumed that a power of P_{abs}=33 μW facilitates absorption by graphene that can contribute to a photocurrent generation.

The absorption coefficient of graphene α_{G} can be calculated from a formula that relates a 2D graphene absorption α_{2D} with the effective thickness of the waveguide t through the expression. Thus, for example:

α_{G}=α_{2D}/t (13)

Taking α_{2D}=2.3% and the effective thickness of the waveguide at t=100 nm, the absorption of graphene was calculated at α_{G}=0.23 dB/μm. Thus, to achieve 50% absorption of power by graphene around 13 μm-long waveguide can be utilized.

### Exemplary Channel PTE Current Generation Principle

Most of the previously reported PTE effects usually refer to the junction formed either by monolayer and bilayer graphene or between regions of graphene with different Fermi energies E_{F}, such as p-n junctions with buried split-gates or with a top-gated control. As discussed above, the main principle of the PTE effect can be creating an asymmetry in the device. Such asymmetry can be created by using two different contact metals (See, e.g., Reference 117) or by using two adjacent graphene regions of different doping.

The photovoltage in this exemplary case can be generated at the junction, and can be driven by the difference in graphene's Seebeck coefficients ΔS=S₁−S₂ on either side of the junction through, for example:

Vₚₕ=ΔSΔT=(S₁(μᵢ)−S₂(μ₂))ΔT (14)

where ΔT can be the electron temperature increase within the junction after photoexcitation and μ can be the chemical potential. The dependence of the photocurrent defined as, for example:

$${I}_{ph} = \frac{Δ S}{R} Δ T \qquad ( 15 )$$

on ΔS, which results in multiple photocurrent sign reversals over a gate voltage sweep due to the non-monotonic dependence of S₁ and S₂ on E_{F}.

Compared to PTE effect, the PV effect relies on the separation and then collection of photoinduced electrons and holes by a built-in electric field leading to a net photocurrent. Thus, for example:

$${I}_{pv} = \frac{{μ}_{mob} Δ}{{σ}_{0} R} ( {tan}^{- 1} \frac{{μ}_{1}}{Δ} - {tan}^{- 1} \frac{{μ}_{2}}{Δ} ) {n}_{z}^{ave} ( y = 0 ) \qquad ( 16 )$$

where μ_{mob} can be the carriers mobility, Δ the width of the neutrality region in the channel graphene, σ₀ the minimum conductivity, R the total resistance, and nₓ the steady state density of photoexcited carrier. Here, μ₁ and μ₂ suggest a chemical potential shift that can result from a different doping level introduced by different metals or biased voltage.

From above photocurrent equation, it can be determined that photoresponse can maximize in the presence of a p-n junction when μ₁ and μ₂ can have an opposite sign. As the polarity of the PV current can be determined solely by the sign of field gradient, there may only be one sign reversal occurring at μ₁=μ₂. Thus, the photovoltage induced by the PV can effect change monotonically with the gate voltage.

For example, the graphene-metal (“G-M”) interface where chemical potential of graphene that can be in contact with metal can be shifted compared to the graphene channel that can be related to the difference in work functions of the materials. (See, e.g., References 144-146). In the exemplary arrangement, the temperature difference can be established across the entire device channel. This can provide a few advantages over narrow p-n junction, as more of the electron heat can be converted into a photovoltage giving rise to a responsivity increase. (See, e.g., References 108 and 109). In contrast to p-n junction PTE, the channel PTE voltage can be driven by entire temperature across the channel as, for example:

Vₚₕ=SΔT=S(μ)ΔT (17)

The Seebeck coefficient S of the graphene channel can be defined as, for example:

$$S ( μ ) = - \frac{{π}^{2} {k}_{B}^{2} T}{3 e} \frac{1 }{σ} \frac{d σ}{d μ} \qquad ( 18 )$$

where k_{B} can be the Boltzman constant, T can be the lattice temperature, e can be the electron charge, σ can be the conductivity of graphene, and μ can be the chemical potential. Consequently, the channel PTE exhibits a single sign change in the channel due to the monotonic dependence of S on μ.

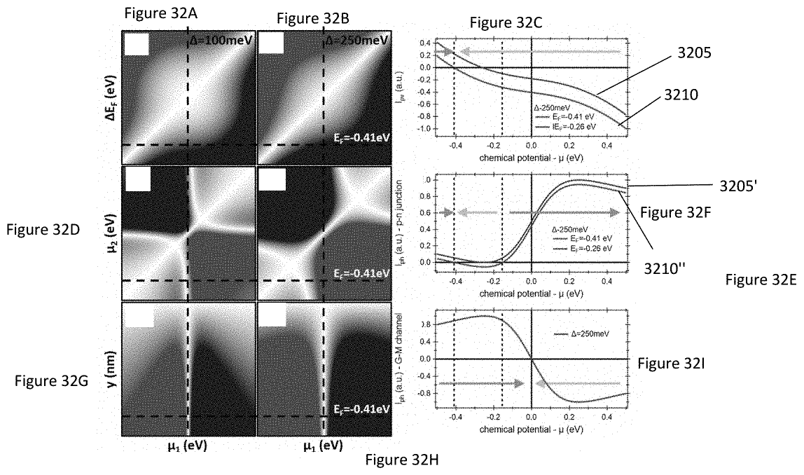

FIG. 31A shows an exemplary diagram illustrating a pointing vector field distribution between a metal stripe contact and an external electrode according to an exemplary embodiment of the present disclosure. FIG. 31B shows an exemplary graph illustrating the temperature rise in graphene as a function of the chemical potential according to an exemplary embodiment of the present disclosure. FIGS. 31C and 31D show exemplary temperature maps for graphene according to an exemplary embodiment of the present disclosure

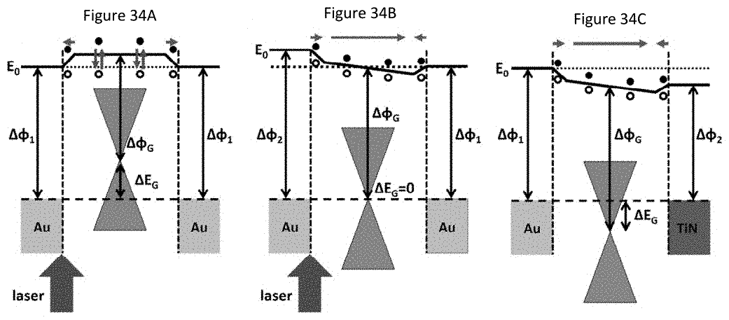

The operation principle of the exemplary LR-DLSPP graphene photodetector can be as follows. The propagating plasmonic mode can reach a maximum in the metal-semiconductor interface (e.g., Contact 2 shown in FIG. 31A), and can decay fast in the direction of an external electrode (e.g., Contact 1 shown in FIG. 31A). The strongly enhanced electromagnetic field from a plasmonic waveguide can improve photo-absorption in the nearby graphene, resulting in efficient and localized carrier heating in the graphene. The carriers can thermalize rapidly, giving rise to the local electron temperature increase. The photoexcited hot electrons can diffuse in a direction of an external electrode (e.g., Contact 1 shown in FIG. 31A) and can create a potential gradient ΔV=−S(y)∇Te(y), where ∇Te(y) can be the temperature gradient of the hot electrons and S(y) can be the Seebeck coefficient. The photocurrent can be collected between the source (e.g., Contact 1 shown in FIG. 31A) and drain (e.g., Contact 2 shown in FIG. 33A) that can be given by, for example:

$${I}_{ph} = \frac{s}{R} Δ T \qquad ( 19 )$$

where R can be the resistance of the graphene sheet. Thus, for example:

$$R = \frac{L}{2 W} ( \frac{{σ}_{1} + {σ}_{2}}{σ \cdot {σ}_{2}} ) \qquad ( 20 )$$

Assuming L=400 nm spacing between electrodes, photodetector length of W=40 μm, and a photodetector operating based on the G-M channel photo-thermoelectric effect (σ₁=σ₂), the graphene sheet resistance was calculated at R˜50Ω at chemical potential μ=0 eV (See, e.g., graph shown in FIG. 33A). In particular, FIG. 33A shows an exemplary graph illustrating the resistance of a graphene sheet for the width of charge neutrality of 25 meV (e.g., line 3305), 100 meV (e.g., line 3310), and 250 meV (e.g., line 3315) according to an exemplary embodiment of the present disclosure

### Exemplary Temperature Distribution

The electron temperature of hot electrons in graphene can be governed by the heat transfer equation, which can be, for example:

κ^{el}∇²Tₑ−γC^{el}(Tₑ−T₀)+P*=0 (21)

where κ^{el} can represent the lateral 2D thermal conductivity and γC^{el} the vertical heat loss, Tₑ can be the electron temperature at a given position, To can be the temperature of the substrate and P* can be the input power density provided by the LR-DSLPP mode. Thermal conductivity κ^{el} can be calculated from the Wiedemman-Franz relation (See, e.g., Reference 138) and expressed by, for example

$${κ}^{el} = \frac{{π}^{2} {k}_{B}^{2} T}{3 {e}^{2}} σ \qquad ( 22 )$$

where k_{B} can be the Boltzman constant, e can be the electron charge, T can be the operation temperature and σ can be the electrical conductivity of the graphene. The 2D electrical conductivity of graphene can depend on the chemical potential/Fermi level shift and can be expressed by, for example:

$$σ ( μ ) = {σ}_{0} ( 1 + \frac{{E}_{F}^{2}}{{Δ}^{2}} ) , {σ}_{0} = 5 ( \frac{{e}^{2}}{h} ) \qquad ( 23 )$$

where σ₀ can denote the minimum conductivity and Δ the spreading of the transfer characteristics. Here σ₀ it was assumed that σ₀=0.193 mS, which can be close to the experimentally achieved value of ˜0.21 mS.

As the electrons in graphene can be thermally isolated from the lattice, the electrons thermal conductivity κ^{el} and the thermal coupling between electrons and lattice γC^{el} can govern the heat dissipation, and can determine the electron temperature distribution. Because of much higher heat capacity of a photon system compared to an electronic one, the photon system can be treated as an ideal thermal bath with T₀ staying constant. Here γ can represent the electron-lattice cooling rate and C^{el} the electron heat capacity. In graphene with a linear electronic dispersion, both parameters can be very small, meaning that the vertical heat dissipation can be mainly limited by the electron-lattice cooling.

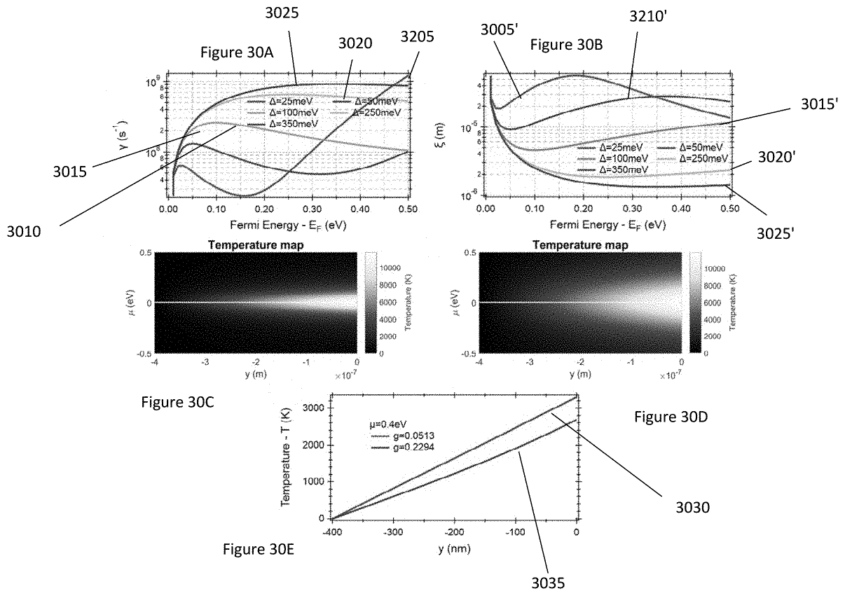

The distance between the peak position of the electron temperature ΔTₑ and the metal contact can be characterized by the cooling length of hot electrons given by ξ=(κ^{el}/γC^{el})^{1/2}. FIGS. 29A-29D are graphs that illustrate the calculated conductivity σ, electron thermal conductivity κ^{el}, electron cooling rate γ, and the electron-lattice cooling length ξ of graphene for 25 meV (e.g., lines 2905, 2905′, 2905″, and 2905′″), 50 meV (e.g., lines 2910, 2910′, 2910″, and 2910′″), 100 meV (e.g., lines 2915, 2915′, 2915″, and 2915′″), 250 meV (e.g., lines 2920, 2920′, 2920″, and 2920′″), and 350 meV (e.g., lines 2925, 2925′, 2925″, and 2925′″) for the width of the neutrality region A. Calculations were performed for the electron-phonon coupling strength g=0.2294. As the carrier-carrier scattering in graphene can be much faster than electron-phonon cooling, it makes graphene ideal material for realizing PTE photodetectors. In such a photodetector, the whole temperature dependence of photocurrent can be through and thus via the cooling rate γ only. For the charge neutrality points between Δ=250 meV and Δ=350 meV the cooling rate was calculated at 10-20 ns⁻¹. (See, e.g., graph shown in FIG. 29C). Thus, ξ drops as the charge neutrality points Δ increases and reaches ξ≈300 nm for Δ=350 meV and the Fermi energy between 300-400 eV. For a cooling length shorter than the photodetector length, the hot carriers strongly thermalize with the lattice before reaching the external electrode. However, for Δ<250, meV the cooling length ξ exceeds the photodetector length of 400 nm. Thus, the energy loss from the electronic system to the lattice can be minimized leading to a high temperature to drive Seebeck coefficient and giving rise to a strong PTE effect.

In comparison, for the lower electron-photon coupling strength g=0.0513, the cooling rate exceeds 0.6 ns⁻¹ even for the charge neutrality point Δ=250 meV in the entire Fermi energies range from 0 eV to 0.5 eV. (See, e.g., graph shown in FIG. 30A). In particular, FIG. 30A shows an exemplary graph illustrating the cooling rate for graphene at the charge neutrality width of 25 meV (e.g., line 3005), 50 meV (e.g., line 3010), 100 meV (e.g., line 3015), 250 meV (e.g., line 3020), and 350 meV (e.g., line 3025) according to an exemplary embodiment of the present disclosure. The cooling length ξ=1.8 μm can be much higher than the photodetector length L=400 nm even for a reasonably high charge neutrality point Δ=250 meV. (See, e.g., graph shown in FIG. 30B). In particular, FIG. 30B shows an exemplary graph illustrating the cooling length for graphene at the charge neutrality width of 25 meV (e.g., line 3005′), 50 meV (e.g., line 3010′), 100 meV (e.g., line 3015′), 250 meV (e.g., line 3020′), and 350 meV (e.g., line 3025′) according to an exemplary embodiment of the present disclosure. It can be even higher for lower Δ exceeding 4.6 μm for Δ=100 meV.

The temperature distribution in the photodetector was calculated using the analytical solution to the heat equation, which can be, for example:

$$Δ T = {T}_{e} ( y ) - {T}_{0} = \frac{ξ sinh ( ( L - \vert y \vert ) / ξ )}{2 cosh ( L / ξ )} ( \frac{{P}^{*}}{{κ}^{el}} ) \qquad ( 24 )$$

where P* can be the rate at which heat enters the system and L can be the photodetector length, for example, a distance between electrodes. As seen from above equation, material parameters that can affect the temperature profile include the thermal conductivity κ^{el}, the electronic specific heat C^{el}, and the electron-lattice cooling rate γ. The combination of these three parameters generates a characteristic cooling length ξ for hot-carrier propagation in the system. As can be seen from FIGS. 30C and 30D and FIGS. 31B-31D, temperature reach maximum exceeds 12,000 K at μ=0 eV, and decays as the chemical potential increases. Assuming a melting temperature of graphene between 4550 K and 6000 K, to reach a maximum temperature in graphene only half of the assumed power of 33 μW can be required, calculated at 16.5 μW. This decay rate can depend on the Δ−the smaller Δ, the faster decays. Simultaneously, the maximum temperature can be localized at the metal stripe (e.g., Contact 2 shown in FIG. 31A) and can decay fast in a direction of the external electrode (e.g., Contact 1 shown in FIG. 31A). When compared with the previous calculations for g=0.2294 (e.g., line 3035 shown in FIG. 30E) where a maximum temperature of 2600 K were calculated for a chemical potential μ=0.4 eV, it can be observed that lower electron-photon coupling strength g=0.0513 (e.g., line 3030 shown in FIG. 30E) can lead to higher temperature T=3200 K under the same chemical potential μ=0.4 eV. In both cases, the calculations were performed for Δ=250 meV.

### Exemplary Photocurrent Map—Operation Regime

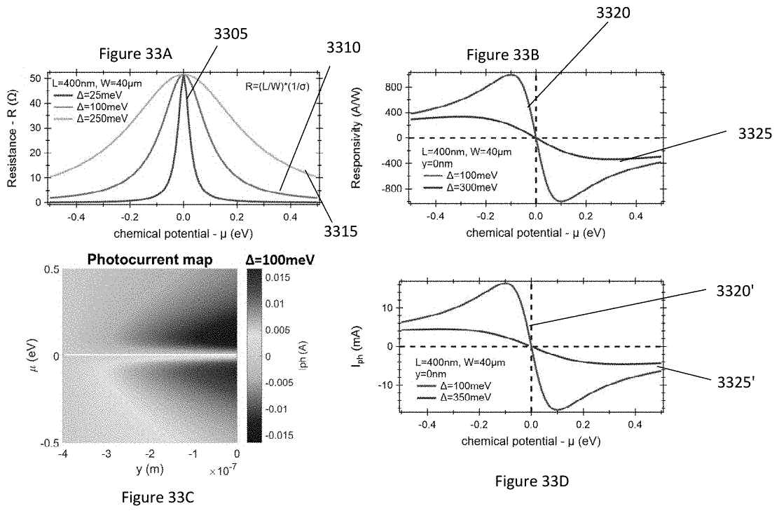

The exemplary photodetector can operate without a need for a bias voltage as the electronic gradient across a graphene channel can be incorporated through an asymmetric electrical contact arrangement. Here one of the photodetector electrodes can serve simultaneously as a metal stripe supporting a propagating mode. Thus, a highly enhanced electric field can be present around this electrode with the maximum localized at the metal, which can decay fast into graphene channel in a direction of the external electrode. As a result, an electronic temperature difference can be established across the channel with built-in potential difference in a channel. FIGS. 32A, 32B, 32D, 32E, 32G, and 32H show exemplary photocurrent maps of the exemplary arrangement according to an exemplary embodiment of the present disclosure under different effects. FIGS. 32C, 32F, and 32I show exemplary graphs illustrating photocurrent versus chemical potential for E_{F}=−0.41 eV (lines 3205 and 3205′), E_{F}=−0.26 eV (e.g., lines 3210 and 3210′) for a photovoltaic (see e.g., FIG. 32C), photo-thermoelectric (“PTE”) p-n junction (see e.g., FIG. 32F) and photo-thermoelectric (PTE) channel effects according to an exemplary embodiment of the present disclosure.

In FIGS. 32G and 32H, the length y and the chemical potential μ₁ dependent photocurrent map is shown for different charge neutrality regions Δ=100 meV and Δ=250 meV that are proper for PTE channel effect. FIGS. 32G-32I illustrate that a photogenerated current Iₚₕ can exhibit a single sign change at the Diract point of graphene what similar to what has been reported earlier for the PTE channel effect. (See, e.g., References 128 and 140). In comparison, in p-n junction PTE the photocurrent can be driven by the difference in graphene's Seebeck coefficients on either side of the junction resulting in multiple photocurrent sign reversals over a gate voltage. Such a behavior can be a clear evidence of the non-monotonic dependence of S₁ and S₂ on E_{F}. (see e.g., FIGS. 32D-32F) The next mechanism responsible for a photovoltage generation can be based on the PV effect in which the photocurrent can be related to ΔE_{F}. (See, e.g., FIGS. 32A-32C). For this effect, a single sign change can be observed at the flat-band point.

As shown in FIGS. 32A-32I, for a chemical potential of −0.41 eV both effects, PV and p-n junction PTE, can be canceled. This potential can correspond to the flat-band condition (See, e.g., Reference 128), for which both a channel graphene and graphene in contact with metal can be doped to the same level. The only effect contributing to a photocurrent here can be the channel PTE. (See, e.g., FIGS. 32A-32I).

### Exemplary Evaluating PTE Performances

For a W=40 μm long photodetector and a distance between electrodes L=400 nm, the resistance of the graphene was calculated as a function of chemical potential for different widths of the neutrality region A. (See, e.g., graph shown in FIG. 33A). As expected, the plot is symmetric with a maximum resistance of ˜50Ω calculated at chemical potential μ=0 eV. The resistance shows a gate-dependent characteristics where doping of graphene increases its conductivity, which reduces the graphene resistance. FIG. 33B shows a responsivity of the G-M photodetector at Pᵢₙ=165 μW (P_{abs}=33 μW) for different widths of the neutrality regions Δ calculated at R=1000 A/W for Δ=100 meV (e.g., line 3520) and R=350 A/W for Δ=300 meV (e.g., line 3325). The two sign change of Iₚₕ along μ=0 eV can reflect the two sign change of the S gradient across the junction. (See, e.g., FIGS. 33C and 33D). In particular, FIG. 33C shows exemplary photocurrent map of the exemplary photodetector according to an exemplary embodiment of the present disclosure and FIG. 33D shows an exemplary graph illustrating the photocurrent as a function of the chemical potential according to an exemplary embodiment of the present disclosure. Iₚₕ can be maximum close to the Δ where S can be largest and drop-off at higher μ, for example, higher doping. As a result, the photocurrent calculated close to the Δ can exceed Iₚₕ=16 mA for low level Δ=100 meV (e.g., line 3320′) and drops to Iₚₕ=4.2 mA for larger Δ=350 meV (e.g., line 3325′).

### Exemplary Asymmetric Metal Arrangement and Operation Speed

It was previously observed that for the exemplary MGM arrangement, with a metal being the Au, a p-type doping of graphene beneath the metal can be observed that can be lower than the intrinsic doping of the graphene channel. A doping induced by a metal can be related with a difference in the work functions of the metal and graphene (Φ_{G}=4.5 eV) (See, e.g., Reference 145) that leads to charge transfer at the contact interface. Depending on the metal, a different type and doping level can be achieved. (See, e.g., References 110, and 144-146). As a results, Ti (Φ_{G}=4.3 eV) can shift the Fermi energy for ΔE_{F}=−230 meV while Au (Φ_{G}=4.7 eV) for ΔE_{F}=250 eV. (See, e.g., Reference 145). This can confirm that Ti contacts can result in n-type doping of graphene while Au contacts can result in p-type doping. (See, e.g., References 144-146).

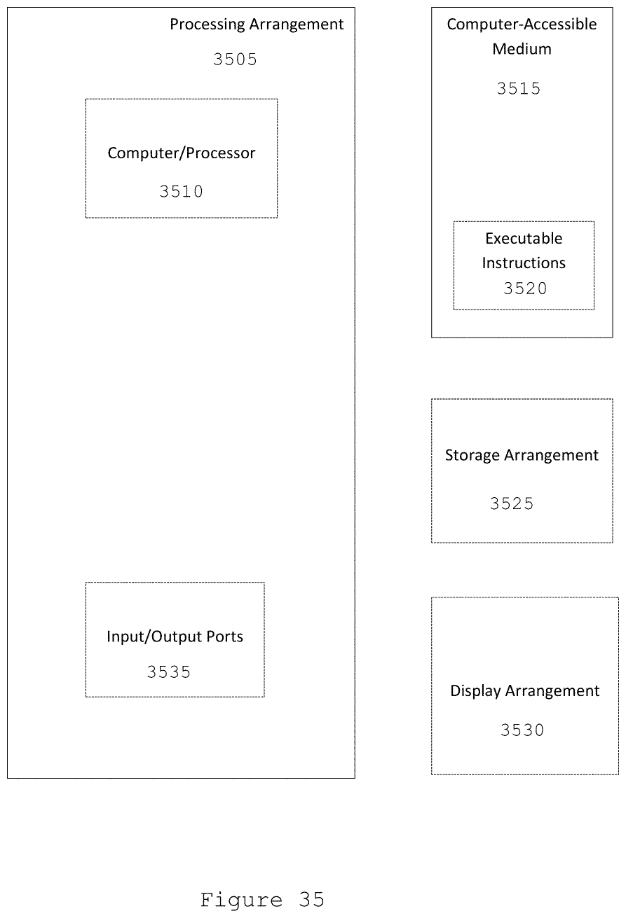

The transit-time-limited bandwidth of the photodetector can be given by, for example:

$${f}_{t} = \frac{3.5}{2 π {t}_{r}} \qquad ( 25 )$$

where tᵣ can be the transit time between metal stripe and external electrode. The exemplary photodetector can operate even at the zero bias voltage as the result of a difference in the Fermi level between two contacts on graphene that can be doped by different metallic electrodes. (See, e.g., FIGS. 34A-34C). In particular, FIGS. 34A-34C show exemplary diagrams of the exemplary graphene photodetector with different source/metal combinations according to an exemplary embodiment of the present disclosure. The built-in electric field can be created. Assuming a carrier velocity of 1.1·10⁵ cm/s (See, e.g., Reference 117), and distance between electrodes of 350 nm, a single transit-time limited bandwidth exceeding 180 GHz can be expected.

As discussed herein, the exemplary photodetector can be based on photo-voltaic, photo-conductive, photo-thermoelectric, photo-bolometric or photo-gaining effect. It can take advantage of additional hot carriers generated in the metal stripe that can be transferred to the graphene or 2D material. Graphene or other 2D material can be below or above a metal stripe, and it can consist of one layer of graphene or 2D material or two or more layers. The exemplary photodetector can be separated by another dielectric material. It can be made of only graphene or a 2D material, or it can be made of graphene and a 2D material together in order to take advantage of the absorption properties of 2D material and the transport properties of graphene. The metal stripe can be in the center of the waveguide or displaced in the waveguide. An external metal electrode can be only on one side of the waveguide or it can be two or more metal electrodes placed on both sides of the waveguide. The metal stripe can be placed directly on top of the semiconductor buffer or inside a semiconductor buffer or inside a semiconductor ridge. The metal stripe and metal electrode(s) can be made from the same material or they can be made from different metallic materials. The external electrodes can be made from the same material or they can be made from different materials. The semiconductor ridge and the semiconductor buffer can be made from the same material or they can be made from different materials. The semiconductor ridge and the semiconductor buffer can be made from any material that meets the requirements of integration with other photonic and electronic components. The semiconductor ridge can have any suitable characteristics (e.g., it can be wider or higher) to meet requirements of coupling efficiency from a photonic waveguide.

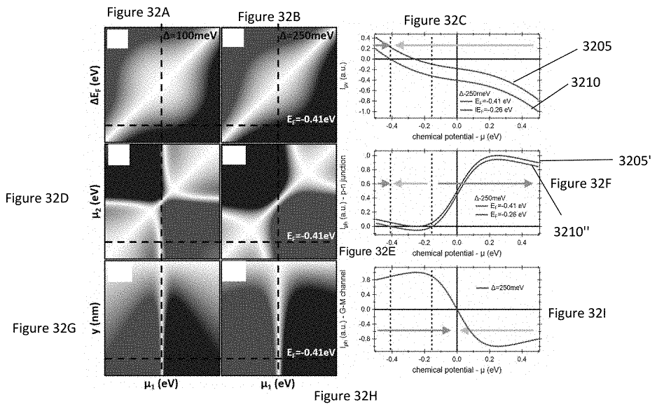

FIG. 35 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 3505. Such processing/computing arrangement 3505 can be, for example entirely or a part of, or include, but not limited to, a computer/processor 3510 that can include, for example one or more microprocessors, and use instructions stored on a computer-accessible medium (e.g., RAM, ROM, hard drive, or other storage device).

As shown in FIG. 35, for example a computer-accessible medium 3515 (e.g., as described herein above, a storage device such as a hard disk, floppy disk, memory stick, CD-ROM, RAM, ROM, etc., or a collection thereof) can be provided (e.g., in communication with the processing arrangement 3505). The computer-accessible medium 3515 can contain executable instructions 3520 thereon. In addition or alternatively, a storage arrangement 3525 can be provided separately from the computer-accessible medium 3515, which can provide the instructions to the processing arrangement 3505 so as to configure the processing arrangement to execute certain exemplary procedures, processes, and methods, as described herein above, for example.

Further, the exemplary processing arrangement 3505 can be provided with or include an input/output ports 3535, which can include, for example a wired network, a wireless network, the internet, an intranet, a data collection probe, a sensor, etc. As shown in FIG. 35, the exemplary processing arrangement 3505 can be in communication with an exemplary display arrangement 3530, which, according to certain exemplary embodiments of the present disclosure, can be a touch-screen configured for inputting information to the processing arrangement in addition to outputting information from the processing arrangement, for example. Further, the exemplary display arrangement 3530 and/or a storage arrangement 3525 can be used to display and/or store data in a user-accessible format and/or user-readable format.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification, drawings and claims thereof, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

### EXEMPLARY REFERENCES

The following references are hereby incorporated by reference in their entireties.
1. D. A. B. Miller, “Attojoule Optoelectronics for Low-Energy Information Processing and Communications,” J. of Lightw. Technol. 35(3), 346-396 (2017).
2. L. C. Kimerling, D-L Kwong, and K. Wada, “Scaling computation with silicon photonics,” MRS Bulletin 39, 687-695 (2014).
3. D. Thomson at el., “Roadmap on silicon photonics,” J. of Optics 18, 073003 (2016).
4. A, Dorodnyy et al., “Plasmonic Photodetectors,” IEEE J. of Selected Topics in Quantum Electronics 24(6), 4600313 (2018).
5. M. Piels and J. E. Bowers, “1—Photodetectors for silicon photonic integrated circuits,” Editor(s): B. Nabet, “Photodetectors,” Woodhead Publishing, 3-20 (2018).
6. G. Li et al., “Improving CMOS-compatible Germanium photodetectors,” Opt. Express 20(24), 26345-26350 (2012).
7. S. Assefa, et al., “CMOS-integrated high-speed MSM germanium waveguide photodetector,” Opt. Express 18(5), 4986-4999 (2010).
8. Y. Salamin, et al., “100 GHz Plasmonic Photodetector,” ACS Photonics 5(8), 3291-3297 (2018).
9. Z. Han, and S. I. Bozhevolnyi, “Radiation guiding with surface plasmon polariton,” Rep. Prog. Phys. 76, 016402 (2013).
10. T. Holmgaard, J. Gosciniak, and S. I. Bozhevolnyi, “Long-range dielectric-loaded surface plasmon-polariton waveguides,” Opt. Express 18(22), 23009-23015 (2010).
11. J. Gosciniak, T. Holmgaard, and S. I. Bozhevolnyi, “Theoretical Analysis of Long-Range Dielectric-Loaded Surface Plasmon Polariton Waveguides,” J. of Lightw. Technol. 29(10), 1473-1481 (2011).
12. B. Sturlesi, M. Grajower, N. Mazurski, and U. Levy, “Integrated amorphous silicon-aluminium long-range surface plasmon polariton (LR-SPP) waveguides,” APL Photonics 3, 036103 (2018).
13. X. Shi, X. Zhang, Z. Han, U. Levy, and S. I. Bozhevolnyi, “CMOS-Compatible Long-Range Dielectric-Loaded Plasmonic Waveguides,” J. of Lightw. Technol. 31(21), 3361-3367 (2013).
14. J. Gosciniak et al., “Thermo-optic control of dielectric-loaded plasmonic waveguide components,” Opt. Express 18(2), 1207-1216 (2010).
15. H. Venghaus and N. Grote, “Fibre Optic Communication: Key Devices,” 2^{nd} Edition, Springer Series in Optical Sciences (2017).
16. C. W. Berry “Significant performance enhancement in photoconductive terahertz optoelectronics by incorporating plasmonic contact electrodes,” Nat. Comm. 4, 1622 (2013).
17. P. R. West, S. Ishii, G. V. Naik, N. K. Emani, V. M. Shalaev, and A. Boltasseva, “Searching for better plasmonic materials,” Laser Photonics Rev. 4(6), 795-808 (2010).
18. J. Gosciniak. J. Justice, U. Khan, M. Modreanu, and B. Corbett, “Study of high order plasmonic modes on ceramic nanodisks,” 25(5), 5244-5244 (2017).
19. C. O. Chui, A. K. Okyay, and K. C. Saraswat, “Effective dark current suppression with asymmetric MSM photodetectors in Group IV semiconductors,” IEEE Photon. Technol. Lett. 15(11), 1585-1587 (2003).
20. H.-J. Zang, et al., “Asymmetrically contacted germanium photodiode using a metal-interlayer-semiconductor-metal structure for extremely large dark current suppression,” Opt. Lett. 41 (16), 3686-3689 (2016).
21. J.-Y. Lin, A. M. Roy, A. Nainani, Y. Sun, K. C. Saraswat, “Increase in current density for metal contacts to n-germanium by inserting TiO2 interfacial layer to reduce Schottky barrier height,” Appl. Phys. Lett. 98 (9), 092113 (2011).
22. D. A. B. Miller, “Attojoule Optoelectronics for Low-Energy Information Processing and Communications,” J. of Lightw. Technol. 35(3), 346-396 (2017).
23. L. C. Kimerling, D-L Kwong, and K. Wada, “Scaling computation with silicon photonics,” MRS Bulletin 39, 687-695 (20140.
24. D. Thomson at el., “Roadmap on silicon photonics,” J. of Optics 18, 073003 (2016).
25. A. N. Grigorenkol, M. Polini and K. S. Novoselov “Graphene plasmonics,” Nature Phot. 6, 747-758 (2012).
26. F. Xia, T. Mueller, Y-M Lin, A. Valdes-Garcia, and P. Avouris, “Ultrafast graphene photodetector,” Nature Nanotech. 4, 839-843 (2009).
27. T. Mueller et al., “Role of contacts in graphene transistors: A scanning photocurrent study,” Phys. Rev. B 79, 245430 (2009).
28. F. H. L. Koppens et al., “Photodetectors based on graphene, other two-dimensional materials and hybrid systems,” Nature Nanotech. 9, 780-793 (2014).
29. J. Wang et al., “High-responsivity graphene-on-silicon slot waveguide photodetectors,” Nanoscale 8, 13206-13211 (2016).
30. D. Schall et al., “50 GBit/s Photodetectors Based on Wafer-Scale Graphene for Integrated Silicon Photonic Communication Systems,” ACS Photon. 1, 781-784 (2014).
31. S. Schuler et al., “Controlled Generation of a p-n Junction in a Waveguide Integrated Graphene Photodetector,” Nano. Lett. 16, 7107-7112 (2016).
32. X. Gan et al., “Chip-integrated ultrafast graphene photodetector with high responsivity,” Nature Phot. 7, 883-887 (2013).
33. J. Wang et al., “High-responsivity graphene-on-silicon slot waveguide photodetectors,” Nanoscale 8, 13206-13211 (2016).
34. T. J. Yoo et al., “Zero-Bias Operation of CVD Graphene Photodetector with Assymetric Metal Contacts,” ACS Photon. 5, 365-370 (2018).
35. S. Cakmakyapan et al., “Gold-patched graphene nano-stripes for high-responsivity and ultrafast photodetection from the visible to infrared regime,” Light: Science & Applications 7, 20 (2018).
36. A. C. Ferrari et al., “Science and technology roadmap for graphene, related two-dimensional crystals, and hybrid systems,” Nanoscale. DOI: 10.1039/c4nr01600a (2014).
37. M. Casalino et al., “Vertically Illuminated, Resonant Cavity Enhanced, Graphene-Silicon Schottky Photodetectors,” ACS Nano 11, 10955-10963 (2017).
38. M. Freitag et al., “Photocurrent in graphene harnessed by tunable intrinsic plasmons,” Nature Nanotech. 4, 1951 (2013).
39. T. J. Echtermeyer et al., “Strong plasmonic enhancement of photovoltage in graphene,” Nature Commun. 2, 458 (2011).
40. T. J. Echtermeyer, et al., “Surface Plasmon Polariton Graphene Photodetectors,” Nano Lett. 16, 8-20 (2016).
41. A. Pospischil et al., “CMOS-compatible graphene photodetector covering all optical communication bands,” Nature Phot. 7, 892-896 (2013).
42. T. J. Echtermeyer et al., “Photothermoelectric and Photoelectric Contributions to Light Detection in Metal-Graphene-Metal Photodetectors,” Nano. Lett. 14, 3733-3742 (2014).
43. T. Holmgaard, J. Gosciniak, and S. I. Bozhevolnyi, “Long-range dielectric-loaded surface plasmon-polariton waveguides,” Opt. Express 18(22), 23009-23015 (2010).
44. J. Gosciniak, T. Holmgaard, and S. I. Bozhevolnyi, “Theoretical Analysis of Long-Range Dielectric-Loaded Surface Plasmon Polariton Waveguides,” J. of Lightw. Technol. 29(10), 1473-1481 (2011).
45. B. Sturlesi, M. Grajower, N. Mazurski, and U. Levy, “Integrated amorphous silicon-aluminium long-range surface plasmon polariton (LR-SPP) waveguides,” APL Photonics 3, 036103 (2018).
46. X. Shi, X. Zhang, Z. Han, U. Levy, and S. I. Bozhevolnyi, “CMOS-Compatible Long-Range Dielectric-Loaded Plasmonic Waveguides,” J. of Lightw. Technol. 31(21), 3361-3367 (2013).
47. S. Muehlbrandt, A. Melikyan, T. Harter, K. Kohnle, A. Muslija, P. Vincze, S. Wolf, P. Jakobs, Y. Fedoryshyn, W. Freude, J. Leuthold, C. Koos, and M. Kohl, “Silicon-plasmonic internal-photoemission detector for 40 Gbit/s data reception,” Optica 3(7), 741-747 (2016).
48. I. Goykhman, U. Sassi, B. Desiatov, N. Mazurski, S. Milana, D. de Fazio, A. Eiden, J. Khurgin, U. Levy, and A. C. Ferrai, “On-Chip Integrated, Silicon-Graphene Plasmonic Schottky Photodetector for High Responsivity and Avalanche Photogain,” Nano Lett. 16(5), 3005-3013 (2016).
49. Y. Salamin et al., “100 Gbit/s Graphene Photodetector,” in Advanced Photonics 2018, OSA Technical Digest paper IW1B.2., OSA (2018).
50. R-J Shiue et al., “High-Responsivity Graphene-Boron Nitride Photodetector and Autocorrelator in a Silicon Photonic Integrated Circuit,” Nano Lett. 15, 7288-7292 (2015).
51. J. Gosciniak and D. T. H. Tan, “Theoretical investigation of graphene-based photonic modulators,” Sci. Rep. 3, 1897 (2013).
52. D. A. B. Miller, “Attojoule Optoelectronics for Low-Energy Information Processing and Communications,” J. of Lightw. Technol. 35(3), 346-396 (2017).
53. L. C. Kimerling, D-L Kwong, and K. Wada, “Scaling computation with silicon photonics,” MRS Bulletin 39, 687-695 (2014).
54. D. Thomson at el., “Roadmap on silicon photonics,” J. of Optics 18, 073003 (2016).
55. Ch. A. Thraskias, at al., “Survey of Photonic and Plasmonic Interconnect Technologies for Intra-Datacenter and High-Performance Computing Communications,” IEEE Comm. Surveys & Tutorials 20(4), Fourth quarter (2018).
56. M. Piels and J. E. Bowers, “1—Photodetectors for silicon photonic integrated circuits,” Editor(s): B. Nabet, “Photodetectors,” Woodhead Publishing, 3-20 (2018).
57. A, Dorodnyy et al., “Plasmonic Photodetectors,” IEEE J. of Selected Topics in Quantum Electronics 24(6), 4600313 (2018).
58. Z. Han, and S. I. Bozhevolnyi, “Radiation guiding with surface plasmon polariton,” Rep. Prog. Phys. 76, 016402 (2013).
59. A. Kumar, et al., “Dielectric-loaded plasmonic waveguide components: going practical,” Laser Photon. Rev. 7 (6), 938-951 (2013).
60. S. Muehlbrandt, et al., “Silicon-plasmonic internal-photoemission detector for 40 Gbit/s data reception,” Optica 3 (7), 741-747 (2016).
61. I. Goykhman, B. Desiatov, J. Khurgin, J. Shappir, and U. Levy, “Locally oxidized silicon surface-plasmon Schottky detector for telecom regime,” Nano Lett. 11(6), 2219-2224 (2011).
62. I. Goykhman, B. Desiatov, J. Khurgin, J. Shappir, and U. Levy, “Waveguide based compact silicon Schottky photodetector with enhanced responsivity in the telecom spectral band,” Opt. Express 20(27), 28594-28602 (2012).
63. I. Goykhman, et al., “On-chip integrated, silicon-graphene plasmonic Schottky photodetector with high responsivity and avalanche photogain,” Nano Lett. 16(5), 3005-3013 (2016).
64. J. Gosciniak, F. B. Atar, B. Corbett, and M. Rasras, “Plasmonic Schottky photodetector with metal stripe embedded into semiconductor and with a CMOS-compatible titanium nitride,” Sci. Rep. 9, 6048 (2019).
65. T. J. Echtermeyer, et al., “Photo-thermoelectric and photoelectric contributions to light detection in metal-graphene-metal photodetectors,” Nano Lett. 14, 3733-3742 (2014).
66. M. Freitag, T. Low, F. Xia, and P. Avouris, “Photoconductivity of biased graphene,” Nat. Photon. 7, 53-59 (2012).
67. P. Ma, Y. Salamin, B. Baeuerle, A. Josten, W. Heni, A. Emboras, and J. Leuthold, “Plasmonically Enhanced Graphene Photodetector Featuring 100 Gbit/s Data Reception, High Responsivity, and Compact Size,” ACS Photonics 6(1), 154-161 (2018).
68. Y. Ding, et al., “Ultra-compact integrated graphene plasmonic photodetector with bandwidth above 110 GHz”, arXiv:1808.04815 (2018).
69. Z. Ma, et al., “Compact Graphene Plasmonic Slot Photodetector on Silicon-on-insulator with High Responsivity”, arXiv:1812.00894 (2018).
70. G. Li et al., “Improving CMOS-compatible Germanium photodetectors,” Opt. Express 20(24), 26345-26350 (2012).
71. S. Assefa, et al., “CMOS-integrated high-speed MSM germanium waveguide photodetector,” Opt. Express 18(5), 4986-4999 (2010).
72. L. Virot, et al., “Integrated waveguide PIN photodiodes exploiting lateral Si/Ge/Si heterojunction,” Opt. Express 25(16), 19487 (2017).
73. D. Benedikovic, et al., “25 Gbps low-voltage hetero-structured silicon-germanium waveguide pin photodetectors for monolithic on-chip nanophotonic architectures,” Photonics Research 7(4), 437 (2019).
74. H. Chen, et al., “100-Gbps RZ Data Reception in 67-GHz Si-Contacted Germanium Waveguide p-i-n Photodetectors,” J. of Lightw. Technol. 35(4) (2017).
75. Y. Salamin, et al., “100 GHz Plasmonic Photodetector,” ACS Photonics 5(8), 3291-3297 (2018).
76. T. Holmgaard, J. Gosciniak, and S. I. Bozhevolnyi, “Long-range dielectric-loaded surface plasmon-polariton waveguides,” Opt. Express 18(22), 23009-23015 (2010).
77. J. Gosciniak, T. Holmgaard, and S. I. Bozhevolnyi, “Theoretical Analysis of Long-Range Dielectric-Loaded Surface Plasmon Polariton Waveguides,” J. of Lightw. Technol. 29(10), 1473-1481 (2011).
78. B. Sturlesi, M. Grajower, N. Mazurski, and U. Levy, “Integrated amorphous silicon-aluminium long-range surface plasmon polariton (LR-SPP) waveguides,” APL Photonics 3, 036103 (2018).
79. X. Shi, X. Zhang, Z. Han, U. Levy, and S. I. Bozhevolnyi, “CMOS-Compatible Long-Range Dielectric-Loaded Plasmonic Waveguides,” J. of Lightw. Technol. 31(21), 3361-3367 (2013).
80. S. Saha, et al., “On-Chip Hybrid Photonic-Plasmonic Waveguides with Ultrathin Titanium Nitride Films,” ACS Photonics 5, 4423-4431 (2018).
81. H. Venghaus and N. Grote, “Fibre Optic Communication: Key Devices,” 2nd Edition, Springer Series in Optical Sciences (2017).
82. C. W. Berry “Significant performance enhancement in photoconductive terahertz optoelectronics by incorporating plasmonic contact electrodes,” Nat. Comm. 4, 1622 (2013).
83. P. R. West, S. Ishii, G. V. Naik, N. K. Emani, V. M. Shalaev, and A. Boltasseva, “Searching for better plasmonic materials,” Laser Photon. Rev. 4(6), 795-808 (2010).
84. J. Gosciniak. J. Justice, U. Khan, M. Modreanu, and B. Corbett, “Study of high order plasmonic modes on ceramic nanodisks,” Opt. Express 25(5), 5244-5244 (2017).
85. C. O. Chui, A. K. Okyay, and K. C. Saraswat, “Effective dark current suppression with asymmetric MSM photodetectors in Group IV semiconductors,” IEEE Photon. Technol. Lett.
15(11), 1585-1587 (2003).
86. H.-J. Zang, et al., “Asymmetrically contacted germanium photodiode using a metal-interlayer-semiconductor-metal structure for extremely large dark current suppression,” Opt. Letters 41 (16), 3686-3689 (2016).
87. J.-Y. Lin, A. M. Roy, A. Nainani, Y. Sun, K. C. Saraswat, “Increase in current density for metal contacts to n-germanium by inserting TiO2 interfacial layer to reduce Schottky barrier height,” Appl. Phys. Lett. 98 (9), 092113 (2011).
88. Yi Zhang, et al., “A high-responsivity photodetector absent metal germanium direct contact,” Opt. Express 22(9), 011367 (2014).
89. D. A. B. Miller, “Attojoule optoelectronics for low-energy information processing and communica-tions,” J. Lightwave Technol. 35, 346-396 (2017).
90. 2. L. C. Kimerling, D.-L. Kwong and K. Wada, “Scaling computation with silicon photonics,” MRS Bull. 39, 687-695 (2014).
91. 3. D. Thomson, A. Zilkie, J. E. Bowers, T. Komljenovic, G. T. Reed, L. Vivien, D. Marris-Morini, E. Cas-san, L. Virot, J. M. Fedeli and J. M. Hartmann, “Roadmap on silicon photonics,” J. Opt. 18, 073003 (2016).
92. M. Piels and J. E. Bowers, “Photodetectors for silicon photonic integrated circuits,” in Photodetec-tors, B. Nabet, ed. (Woodhead Publishing, 2018), pp. 3-20
93. L. Chrostowski and M. Hochberg, “Silicon Photonics Design: From Devices to Systems,” (Cambridge University Press, Glasgow, 2015).
94. J. Wang and S. J. Lee, “Ge-Photodetectors for Si-Based Optoelectronic Integration,” Sensors. 11, 696-718 (2011).
95. L. Vivien, A. Polzer, D. Marris-Morini, J. Osmond, J. M. Hartmann, P. Crozat, E. Cassan, Ch. Kopp, H. Zimmermann and J. M. Fedeli, “Zero-bias 40 Gbit/s germanium waveguide photodetector on sili-con,” Opt. Express 20, 1096 (2012).
96. A. Rogalski, “Infrared detectors: status and trends,” Prog. Quant. Electron. 27, 59-210 (2003).
97. Y. Liu, S. R. Forrest, J. Hladky, M. J. Lange, G. H. Olsen, and D. E. Ackley, “A planar InP/InGaAs ava-lanche photodiode with floating guard ring and double diffused junction,” IEEE J. Lightw. Technol. 10, 182-193 (1992).
98. J. Gosciniak, F. B. Atar, B. Corbett, and M. Rasras, “Plasmonic Schottky photodetector with metal stripe embedded into semiconductor and with a CMOS-compatible titanium nitride,” Sci. Rep. 9(1), 6048, (2019).
99. A. H. Castro Neto, F. Guinea, N. M. R. Peres, K. S. Novoselov, and A. K. Geim, “The electronic properties of graphene, Rev. Mod. Phys. 81, 109-162 (2009).
100. F. Bonaccorso, Z. Sun, T. Hasan, and A. C. Ferrari, “Graphene photonics and optoelectronics,” Nat. Photon. 4, 611-622 (2010).
101. A. N. Grigorenkol, M. Polini, and K. S. Novoselov “Graphene plasmonics,” Nature Phot. 6, 747-758 (2012).
102. F. Xia, T. Mueller, Y-M Lin, A. Valdes-Garcia, and P. Avouris, “Ultrafast graphene photodetec-tor,” Nature Nanotech. 4, 839-843 (2009).
103. F. Wang, Y. Zhang, Ch. Tian, C. Girit, A. Zettl, M. Crommie, and Y. Ron Shen, “Gate-variable op-tical transitions in graphene,” Science 320, 206-209 (2008).
104. S. Castilla, B. Terres, M. Autore, L. Viti, J. Li, A. Y. Nikitin, I. Vangelidis, K. Watanabe, T. Tanigu-chi, E. Lidorikis, M. S. Vitiello, R. Hillenbrand, K.-J. Tielrooij, and F. H. L. Koppens, “Fast and Sensitiv-ie Terahertz Detection Using and Antenna-Integrated Graphene pn Junction,” Nano Lett. 19, 2765-2773, 2019.
105. A. Pospischil, M. Humer, M. M. Furchi, D. Bachmann, R. Guider, T. Fromherz, and T. Mueller, “CMOS-compatible graphene photodetector covering all optical communication bands,” Nat. Pho-tonics 7, 892 (2013).
106. S. Goossens, G. Navickaite, C. Monasterio, S. Gupta, J. J. Piqueras, R. P'erez, G. Burwell, I. Ni-kitskiy, T. Lasanta, T. Garan, E. Puma, A. Centeno, A. Pesquera, A. Zurutuza, G. Konstantatos, and F. Koppens, “Broadband image sensor array based on graphene-CMOS integration,” Nat. Photon-ics 11, 366 (2017).
107. J. Wang, Z. Cheng, Z. Chen, X. Wan, B. Zhu, H. Ki Tsang, Ch. Shu, and J. Xua, “High-responsivity graphene-on-silicon slot waveguide photodetectors,” Nanoscale 8, 13206-13211 (2016).
108. S. Schuler, D. Schall, D. Neumaier, B. Schwarz, K. Watanabe, T. Taniguchi, and T. Mueller, “Gra-phene Photodetector Integrated on a Photonic Crystal Defect Waveguide,” ACS Photonics 5, 4758-4763, (2018).
109. S. Schuler, D. Schall. D. Neumaier, L. Dobusch, O. Bethge, B. Schwarz, M. Krall, and T. Mueller, “Controlled Generation of a p-n Junction in a Waveguide Integrated Graphene Photodetector,” Nano. Lett. 16, 7107-7112, (2016).
110. X. Gan, R.-J. Shiue, Y. Gao, I. Meric, T. F. Heinz, K. Shepard, J. Hone, S. Assefa, and D. Englund, “Chip-integrated ultrafast graphene photodetector with high responsivity,” Nature Phot. 7, 883-887 (2013).
111. I. Goykhman, U. Sassi, B. Desiatov, N. Mazurski, S. Milana, D. de Fazio, A. Eden, J. Khurgin, J. Shappir, U. Levy, and A. C. Ferrari, “On-chip integrated, silicon-graphene plasmonic Schottky pho-todetector with high responsivity and avalanche photogain,” Nano Lett. 16(5), 3005-3013, 2016.
112. R.-J. Shiue, Y. Gao, Y. Wang, Ch. Peng, A. D. Robertson, D. K. Efetov, S. Assefa, F. H. L. Kop-pens, J. Hone, and D. Englund, “High-Responsivity Graphene-Boron Nitride Photodetector and Au-tocorrelator in a Silicon Photonic Integrated Circuits,” Nano Lett. 15, 7288-7293, 2015.
113. M. Freitag, T. Low, F. Xia, and P. Avouris, “Photoconductivity of biased graphene,” Nat. Pho-tonics 7, 53-59 (2012).
114. J. E. Muench, A. Ruocco, M. A. Giambra, V. Miseikis, D. Zhang, J. Wang, H. F. Y. Watson, G. C. Park, A. Akhavan, V. Sorianello, M. Midrio, A. Tomadin, C. Coletti, M. Romagmoli, A. C. Ferrari, and I. Goykhman, “Waveguide-integrated, plasmonic enhanced graphene photodetectors,” arXiv:1905.04639v1, (2019).
115. Ch.-H. Liu, Y.-Ch. Chang, T. B. Norris, and Z. Zhong, “Graphene photodetectors with ultra-broadband and high responsivity at room temperature,” Nature Nanotech. 9, 273-278, (2014).
116. T. J. Echtermayer, S. Milana, U. Sassi, A. Eiden, M. Wu, E. Lidorikis, and A. C. Ferrari, “Surface Plasmon Polariton Graphene Photodetectors,” Nano Lett. 16, 8-20, (2016).
117. Y. Ding, Z. Cheng, X. Zhu, K. Yvind, J. Dong, M. Galili, H. Hu, N. A. Mortensen, S. Xiao, and L. K. Oxenlowe, “Ultra-compact integrated plasmonic photodetector with bandwidth above 110 GHz,” DOI: https://doi.org/10.1515/nanoph-2019-0167 (2019).
118. Z. Ma, K. Kikunage, H. Wang, S. Sun, R. Amin, M. Tahersima, R. Maiti, M. Miscuglio, H. Dalir, and V. J. Sorger, “Compact Graphene Plasmonic Slot Photodetector on Silicon-on-insulator with High Responsivity,” arXiv.:1812.00894v1, (2018).
119. F. Xia, T. Mueller, Y-M. Lin, A. Valdes-Garcia, and P. Avouris, “Ultrafast graphene photodetector,” Nature Nanotech. 4, 839-843 (2009).
120. T. Mueller, F. Xia, and P. Avouris, “Graphene photodetectors for high-speed optical communi-cations,” Nature Phot. 4, 297-301 (2010).
121. T. J. Echtermeyer, P. S. Nene, M. Trushin, R. V. Gorbachev, A. L. Eiden, S. Milana, Z. Sun. J. Schliemann, E. Lidorikis, K. S. Novoselov, and A. C. Ferrari, “Photothermoelectric and Photoelectric Contributions to Light Detection in Metal-Graphene-Metal Photodetectors,” Nano Lett. 14(7), 3733-3742 (2014).
122. N. Youngblood, Y. Anugrah, R. Ma, S. J. Koester, and M. Li, “Multifunctional Graphene Optical Modulator and Photodetector Integrated on Silicon Waveguides,” Nano Lett. 14, 2741-2746 (2014).
123. J. Yan, M-H. Kim, J. A. Elle, A. B. Sushkov, G. S. Jenkins, H. M. Milchberg, M. S. Fuhrer and H. D. Drew, “Dual-gated bilayer graphene hot-electron bolometer,” Nature Nanotech. 7, 472-478 (2012).
124. R-J. Shiue, Y. Gao, Ch. Tan, Ch. Peng, J. Zheng, D. K. Efetov, Y. Duck Kim, J. Hone and D. En-glund, “Thermal radiation control from hot graphene electrons coupled to a photonic crystal nanocavity,” Nature Commun. 10, 109 (2019).
125. E. D. Walsh, D. K. Efetov, G.-H. Lee, M. Heuck, J. Crossno, T. A. Ohki, P. Kim, D. Englund, and K. Ch. Fong, “Graphene-Based Josephson-Junction Single-Photon Detector,” Phys. Rev. Appl. 8, 024022 (2017).
126. X. Du, D. E. Prober, H. Vora, and Ch. B. Mckitterick, “Graphene-based Bolometers,” Graphene 2D Mater. 1, 1-22 (2014).
127. P. Ma, Y. Salamin, B. Baeuerle, A. Josten, W. Heni, A. Emboras, and J. Leuthold, “Plasmonically Enhanced Graphene Photodetector Featuring 100 Gbit/s Data Reception, High Responsivity and Compact Size,” ACS Photonics 6(1), 154-161, (2018).
128. V. Shautsova, T. Sidiropoulos, X. Xiao, N. A. Gusken, N. C. G. Black, A. M. Gilbertson, V. Gianni-ni, S. Maier, L. F. Cohen, and R. F. Oulton, “Plasmon inducer thermoelectric effect in graphene,” Nature Comm. 9, 5190, (2018).
129. J. F. Sierra, I. Neumann, J. Cuppens, B. Raes, M. V. Costache, and S. O. Valenzuela, “Thermoe-lectric spin voltage in graphene,” Nature Nanotech. 13, 107-111, (2018).
130. X. Xu, N. M. Gabor, J. S. Alden, A. M. van der Zande, and P. L. McEuen, “Photo-Thermoelectric Effect at a Graphene Interface Junction,” Nano Lett. 10, 562-566, (2010).
131. T. J. Echtermeyer, P. S. nene, M. Trushin, R. V. Gorbachev, A. L. Eiden, S. Milana, Z. Sun, J. Schliemann, E. Lidorikis, K. S. Novoselov, and A. C. Ferrari, “Photothermoelectric and Photoelectric Contributions to Light Detection in Metal-Graphene-Metal Photodetectors,” Nano Lett. 14, 3733-3742, (2014). PTE
132. N. M. Gabor, J. C. W. Song, Q. Ma, N. L. Nair, T. Taychatanapat, K. Watanabe, T. Taniguchi, L. S. Levitov, P. Jarillo-Herrero, “Hot Carrier-Assisted Intrinsic Photoresponse in Graphene,” Science 334(6056), 648-652, (2011).
133. J. C. W. Song, M. S. Rudner, Ch. M. Marcus, and L. S. Levitov, “Hot Carrier Transport and Photo-current in Graphene,” Nano Lett. 11, 4688-4692, (2011),
134. J. F. Sierra, I. Neumann, M. V. Costache, and S. O. Valenzuela, ‘Hot-Carrier Seebeck Effect: Dif-fusion and Remote Detection of Hot Carriers in Graphene,” Nano Lett. 15, 4000-4005, (2016).
135. P. Ch. Eng, S. Song, and B. Ping, “State-of-the-art photodetectors for optoelectronic integra-tion at telecommunication wavelength,” Nanophotonics 4(3), 277-302 (2015).
136. J. H. Los, K. V. Zakharchenko, M. I. Katsnelson, and A. Fasolino, “Melting temperature of gra-phene,” Phys. Rev. B 91, 045415 (2015).
137. Y. Lin, Q. Ma, P-Ch. Shen, B. Ilyas, Y. Bie, A. Liao, E. Ergecen, B. Han, N. Mao, X. Zhang, X. Ji, Y. Zhang, J. Yin, S. Huang, M. Dresselhaus, N. Gedik, P. Jarillo-Herrero, X. Ling, J. Kong, and T. Palacios, “Asymmetric hot-carrier thermalization and broadband photoresponse in graphene-2D semicon-ductor lateral heterojunctions,” Sci. Adv. 5, eaav1493, (2019).
138. Q. Ma, N. M. Gabor, T. I. Andersen, N. L. Nair, K. Watanabe, T. Taniguchi, and P. Jarillo-Herrero, “Competing Channels for Hot-Electron Cooling in Graphene,” Phys. Rev. Lett. 112, 247401, (2014).
139. K. J. Tielrooij, L. Piatkowski, M. Massicotte, A. Woessner, Q. Ma, Y. Lee, K. S. Myhro, C. N. Lau, P. Jarillo-Herrero, N. F. van Hulst, and F. H. L. Koppens, “Generation of photovoltage in graphene on a femtosecond timescale through efficient carrier heating,” Nature Nanotech. 10, 437-443, 2015.
140. K. J. Tielrooij, M. Massicotte, L. Piatkowski, A. Woessner, Q. Ma, P. Jarillo-Herrero, N. F. van Hulst, and F. H. L. Koppens, “Hot-carrier photocurrent effects at graphene-metal interfaces,” J. Phys.: Condens. Matter 27, 164207, 2015.
141. S. Schuler, D. Schall. D. Neumaier, L. Dobusch, O. Bethge, B. Schwarz, M. Krall, and T. Mueller, “Controlled Generation of a p-n Junction in a Waveguide Integrated Graphene Photodetector,” Nano. Lett. 16, 7107-7112, 2016.
142. D. Efetov, P. Kim, “Controlling electron-phonon interactions in graphene at ultrahigh carrier densities,” Phys. Rev. Lett. 105, 256805, (2010).
143. D. Brida, A. Tomadin, C. Manzoni, Y. J. Kim, A. Lombardo, S. Milana, R. R. Nair, K. S. Novoselov, A. C. Ferrari, G. Cerullo, M. Polini, “Ultrafast collinear scattering and carrier multiplication in gra-phene,” Nature Comm. 4, 1987 (2013).
144. E. J. H. Lee, K. Balasubramanian, R. T. Weitz, M. Burghard, and K. Kern, “Contact and edge ef-fects in graphene devices,” Nature Nanotech. 3, 486-490, (2008).
145. G. Giovannetti, P. A. Khomyakov, G. Brocks, V. M. Karpan, J. van den Brink, and P. J. Kelly, “Doping Graphene with Metal Contacts,” Phys. Rev. Lett. 101, 026803, (2008).
146. T. J. Yoo, Y. J. Kim, S. K. Lee, Ch. G. Kang, K. E. Chang, H. J. Hwang, N. Revannath, and B. H. Lee, “Zero-Bias Operation of CVD Graphene Photodetector with Asymmetric Metal Contacts,” ACS Photonics 2018, 5, 365-370 (2018).
147. J. Gosciniak, T. Holmgaard, and S. I. Bozhevolnyi, “Theoretical analysis of long-range-dielectric loaded surface plasmon polariton waveguides,” J. of Lightw. Technol. 26(10), 1473-1481, 2011.
148. T. Holmgaard, J. Gosciniak, and S. I. Bozhevolnyi, Long-range dielectric-loaded surface plas-mon-polariton waveguides,” Opt. Express 18(22), 23009-23015, (2010).
149. B. Sturlesi, M. Grajower, N. Mazurski, and U. Levy, “Integrated amorphous silicon-aluminum long-range surface plasmon polariton (LR-SPP) waveguides,” APL Photonics 3, 036103 (2018).
150. J. Gosciniak, and M. Rasras, “High-bandwidth and high-responsivity waveguide-integrated plasmonic germanium photodetector,” JOSA B 36(9), 2481, (2019).
151. D. Ansell, I. P. Radko, Z. Han, F. J. Rodriguez, S. I. Bozhevolnyi and A. N. Grigorenko, “Hybrid graphene plasmonic waveguide modulators,” Nature Commun. 6, 8846 (2015).

What is claimed is:

1. A photodetector, comprising:
a metal contact;
a metal stripe coupled to the metal contact; and
at least one photon absorbing material surrounding the metal stripe on at least four sides of the metal stripe.

2. The photodetector of claim 1, wherein the at least one photon absorbing material is germanium.

3. The photodetector of claim 1, wherein the at least one photon absorbing material is configured to absorbs photons in a wavelength range of about 1.1 μm to about 1.71 μm.

4. The photodetector of claim 1, further comprising a further metal contact disposed on the at least one photon absorbing material.

5. The photodetector of claim 4, further comprising at least one voltage generator configured to apply a bias voltage between the metal contact and the further metal contact to generate an electric field in the at least one photon absorbing material.

6. The photodetector of claim 1, wherein the metal contact is disposed on the at least one photon absorbing material.

7. The photodetector of claim 1, further comprising a semiconductor layer, wherein the at least one photon absorbing material is disposed on the semiconductor layer.

8. The photodetector of claim 7, wherein the semiconductor layer is silicon dioxide.

9. The photodetector of claim 7, further comprising at least one further photon absorbing material disposed on the semiconductor layer adjacent to the at least one photon absorbing material.

10. The photodetector of claim 9, wherein the at least one further photon absorbing material is silicon.

11. The photodetector of claim 10, wherein the at least one further photon absorbing material includes a slab and a ridge extending from the slab.

12. The photodetector of claim 10, further comprising a low refractive index substrate, wherein the semiconductor layer is disposed on the low refractive index substrate.

13. The photodetector of claim 1, wherein the at least one photon absorbing material includes a slab and a ridge extending from the slab, and wherein the metal contact is disposed on the slab and the metal strip is one of (i) disposed between the ridge and the slab, (ii) disposed entirely in the ridge, or (iii) inside the slab.

14. The photodetector of claim 1, wherein the metal contact and the metal strip are composed of one of Titanium nitride, aluminum, copper, silver, gold, or zirconium nitride.

15. A photodetector, comprising:
a metal contact;
a metal stripe coupled to the metal contact; and
at least one layer of graphene located between the metal stripe and a semiconductor layer.

16. The photodetector of claim 15, wherein the at least one layer of graphene is coupled to the metal contact.

17. The photodetector of claim 15, further comprising at least one further metal contact, wherein the at least one layer of graphene is coupled to the at least one further metal contact.

18. The photodetector of claim 15, further comprising at least one photon absorbing material surrounding the metal stripe on at least four sides of the metal stripe

19. The photodetector of claim 18, wherein the at least one photon absorbing material is germanium.

20. The photodetector of claim 19, wherein the metal contact is disposed on the at least one photon absorbing material.
